(19) United States
(12) Patent Application Publication
(10) Pub. No.: US 2023/0134388 A1
(43) Pub. Date: May 4, 2023

(54) ENERGY STORAGE SYSTEM

(71) Applicant: LG ELECTRONICS INC., Seoul (KR)

(72) Inventors: Chungki KO, Seoul (KR); Injung JEON, Seoul (KR)

(73) Assignee: LG ELECTRONICS INC., Seoul (KR)

(21) Appl. No.: 17/645,273

(22) Filed: Dec. 20, 2021

(30) Foreign Application Priority Data
Nov. 3, 2021 (KR) 10-2021-0149666

(51) Int. Cl. H01M 10/04; H02J 7/00

(52) U.S. Cl. CPC H01M 10/0445; H02J 7/0024

(57) ABSTRACT

An energy storage system according to an embodiment of the present disclosure includes: a plurality of cell arrays, each including a respective plurality of battery cells connected in parallel; and a plurality of switches coupled to the plurality of cell arrays, and configured to connect the plurality of cell arrays in series, wherein the plurality of switches are operable to connect the plurality of cell arrays in parallel.

### CROSS-REFERENCE TO RELATED APPLICATION

Pursuant to 35 U.S.C. § 119(a), this application claims the benefit of earlier filing date and right of priority to Korean Patent Application No. 10-2021-0149666, filed on Nov. 3, 2021, the contents of which are incorporated herein by reference in its entirety.

### BACKGROUND OF THE INVENTION

### 1. Field of the Invention

The present disclosure relates to an energy storage system, and more particularly, to a battery-based energy storage system and an operating method thereof.

### 2. Description of the Related Art

An energy storage system is a system that stores or charges external power, and outputs or discharges stored power to the outside (e.g., an external entity). To this end, the energy storage system includes a battery, and a power conditioning system that is used for supplying power to the battery or outputting power from the battery.

In order to increase the total battery capacity, battery cells may be connected and used. Battery cells may be chemically and physically different (e.g., from each other), and thus there may be a difference in capacity.

The total capacity of battery is determined according to a series/parallel connection structure (or configuration) of the battery cells. In a high-voltage series configuration, as a difference in capacity between battery cells or sets of battery cells increases while charging/discharging is repeated (or maintained), there is a problem in that the battery capacity that can be used by consumers compared to the total capacity of the battery is reduced. In addition, some batteries may be overcharged due to battery imbalance.

Since the energy storage system has the possibility of accidents such as explosion, ignition, and gas emission, various technologies have been proposed to improve safety. For example, Korean Patent Publication No. 2006-0059680 discloses a circuit for protecting circuits and battery cells from short circuit and overvoltage, and Korean Patent Publication No. 2018-0103212 discloses a battery and battery protection circuit.

### SUMMARY OF THE INVENTION

Embodiments of the present invention have been made in view of the above problems, and an object of an embodiment of the present disclosure is to provide an energy storage system capable of improving the lifespan, stability, and efficiency of a battery by reducing a voltage difference between batteries.

Another object of an embodiment of the present disclosure is to provide an energy storage system capable of reducing the possibility of ignition by preventing overcharging due to battery imbalance.

Another object of an embodiment of the present disclosure is to provide an energy storage system capable of preventing (e.g., at an earlier time) complete discharge of a battery and improving battery lifespan.

Another object of an embodiment of the present disclosure is to provide an energy storage system capable of balancing battery imbalance with a small number of switches.

Another object of an embodiment of the present disclosure is to easily (or readily) implement a series/parallel configuration of a desired capacity, and provide an energy storage system with a high degree of freedom in designing a battery cell module.

In order to achieve the above object, the energy storage system according to embodiments of the present disclosure may improve the lifespan, stability, and efficiency of a battery by changing a battery connection structure (or configuration).

In order to achieve the above object, the energy storage system according to embodiments of the present disclosure uses cell arrays, each including battery cells connected in parallel, the cell arrays connected in a series structure (or configuration), and then converts the cell arrays into a parallel configuration, thereby preventing battery imbalance.

In order to achieve the above object, in the energy storage system according to embodiments of the present disclosure, a main circuit configuration may be separated to protect a control circuit from a problem inside the battery pack.

The energy storage system according to an embodiment of the present disclosure includes: a plurality of cell arrays, each including a respective plurality of battery cells connected in parallel; and a plurality of switches coupled to the plurality of cell arrays, and configured to connect the plurality of cell arrays in series, wherein the plurality of switches are operable to connect the plurality of cell arrays in parallel.

The plurality of switches may include a single pole double throw (SPDT) switch.

One switch may be coupled to a positive terminal of the plurality of cell arrays, and one switch may be coupled to a negative terminal of the plurality of cell arrays.

The plurality of switches may be configured to be operated such that a positive terminal of one of the plurality of cell arrays is connected to a negative terminal of another one of the plurality of cell arrays, and then, positive terminals of the plurality of cell arrays are connected to each other and negative terminals of the plurality of cell arrays are connected to each other.

A number of the plurality of switches may be equal to two times a number of the plurality of cell arrays connected in series.

The energy storage system according to an embodiment of the present disclosure may further include: a battery management system configured to control the plurality of switches based on a voltage difference of the plurality of cell arrays.

During charging, in a state in which a full charge condition is satisfied, the battery management system may be further configured to change a connection state of the plurality of cell arrays from a series configuration to a parallel configuration based on the voltage difference of the plurality of cell arrays being equal to or greater than a first reference value.

In a parallel configuration state, the battery management system may be further configured to change a connection state of the plurality of cell arrays from a parallel configuration to a series configuration based on the voltage difference of the plurality of cell arrays being less than a second reference value.

The battery management system may be further configured to change a connection state of the plurality of cell arrays from a series configuration to a parallel configuration based on the voltage difference of the plurality of cell arrays being equal to or greater than a certain reference value, and change the connection state of the plurality of cell arrays from the parallel configuration to the series configuration based on a preset time elapsing.

The battery management system may be further configured to turn off some internal power sources of the energy storage system and operate the plurality of switches.

The energy storage system according to an embodiment of the present disclosure may further include: a plurality of battery packs, each including a respective plurality of cell arrays.

The battery management system may further include: battery pack circuit boards disposed in each of the plurality of battery packs, and configured to obtain state information of the plurality of battery cells of each battery pack; and a main circuit board coupled to the battery pack circuit boards by a communication line, and configured to receive state information obtained from each battery pack by the battery pack circuit boards.

The plurality of battery packs may be connected in series by a power line, and the power line may be connected to the main circuit board.

The energy storage system according to an embodiment of the present disclosure may further include: a plurality of bus bars to which the plurality of battery cells connected in parallel are connected.

One input terminal of the plurality of switches may be coupled to a positive terminal or a negative terminal of the plurality of cell arrays, and two output terminals of the plurality of switches may be coupled to different bus bars.

The energy storage system according to another embodiment of the present disclosure includes a plurality of battery packs including a first battery module, a second battery module disposed to face the first battery module, and a high current bus bar connecting the first battery module and the second battery module, wherein each of the first battery module and the second battery module includes: a plurality of cell arrays, each including a respective plurality of battery cells connected in parallel; and a plurality of switches coupled to the plurality of cell arrays and configured to connect the plurality of cell arrays in series, wherein the plurality of switches are operable to connect the plurality of cell arrays in parallel.

The plurality of switches may include a single pole double throw (SPDT) switch.

The energy storage system according to another embodiment of the present disclosure may further include a battery management system configured to control the plurality of switches based on a voltage difference of the plurality of cell arrays.

During charging, in a state in which a full charge condition is satisfied, the battery management system is further configured to change a connection state of the plurality of cell arrays from a series configuration to a parallel configuration based on the voltage difference of the plurality of cell arrays being equal to or greater than a first reference value.

In a parallel configuration state, the battery management system may be further configured to change a connection state of the plurality of cell arrays from a parallel configuration to a series configuration based on the voltage difference of the plurality of cell arrays being less than a second reference value.

### BRIEF DESCRIPTION OF THE DRAWINGS

The above and other objects, features and advantages of the present disclosure will be more apparent from the following detailed description in conjunction with the accompanying drawings, in which:

FIGS. 1A and 1B are conceptual diagrams of an energy supply system including an energy storage system according to an embodiment of the present disclosure;

FIG. 2 is a conceptual diagram of a home energy service system including an energy storage system according to an embodiment of the present disclosure;

FIGS. 3A and 3B are diagrams illustrating an energy storage system installation type according to an embodiment of the present disclosure;

FIG. 4 is a conceptual diagram of a home energy service system including an energy storage system according to an embodiment of the present disclosure;

FIG. 5 is an exploded perspective view of an energy storage system including a plurality of battery packs according to an embodiment of the present disclosure;

FIG. 6 is a front view of an energy storage system in a state in which a door is removed;

FIG. 7 is a cross-sectional view of one side of the energy storage system of FIG. 6;

FIG. 8 is a perspective view of a battery pack according to an embodiment of the present disclosure;

FIG. 9 is an exploded view of a battery pack according to an embodiment of the present disclosure;

FIG. 10 is a perspective view of a battery module according to an embodiment of the present disclosure;

FIG. 11 is an exploded view of a battery module according to an embodiment of the present disclosure;

FIG. 12 is a front view of a battery module according to an embodiment of the present disclosure;

FIG. 13 is an exploded perspective view of a battery module and a sensing substrate according to an embodiment of the present disclosure;

FIG. 14 is a perspective view of a battery module and a battery pack circuit substrate according to an embodiment of the present disclosure;

FIG. 15A is a side view of the battery module and the battery pack circuit substrate of FIG. 14 in a coupled state;

FIG. 15B is another side view of the battery module and the battery pack circuit substrate of FIG. 14 in a coupled state;

FIG. 16 is a diagram illustrating a connection between the battery pack and a battery management system according to an embodiment of the present disclosure;

FIGS. 17A to 17C are diagrams illustrating a battery imbalance;

FIGS. 18 to 20 are diagrams illustrating a battery connection structure (or configuration) according to an embodiment of the present disclosure; and

FIG. 21 is a flowchart illustrating a method of operating an energy storage system according to an embodiment of the present disclosure.

### DETAILED DESCRIPTION OF THE PREFERRED EMBODIMENTS

Hereinafter, embodiments of the present disclosure will be described in detail with reference to the accompanying drawings. However, it is understood that the present disclosure is not limited to these embodiments and may be modified in various forms.

In the drawings, in order to clearly and briefly describe embodiments of the present disclosure, the illustration of parts irrelevant to the description is omitted, and the same reference numerals are used for the same or extremely similar parts throughout the specification.

Hereinafter, the suffixes “module” and “unit” of elements herein are used for convenience of description and thus may be used interchangeably and do not have any distinguishable meanings or functions. Thus, the terms “module” and “unit” may be interchangeably used.

It will be understood that, although the terms “first”, “second”, etc. may be used herein to describe various elements, these elements should not be limited by these terms. These terms are only used to distinguish one element from another element.

The labels top U, bottom D, left Le, right Ri, front F, and rear R used in the drawings are used to describe a battery pack and an energy storage system including the battery pack, and may be set differently according to standard.

The labels indicating height direction (h+, h-), length direction (1+, 1-), and width direction (w+, w-) of the battery module used in FIGS. 10 to 13 are used to describe the battery module, and may be set differently according to standard.

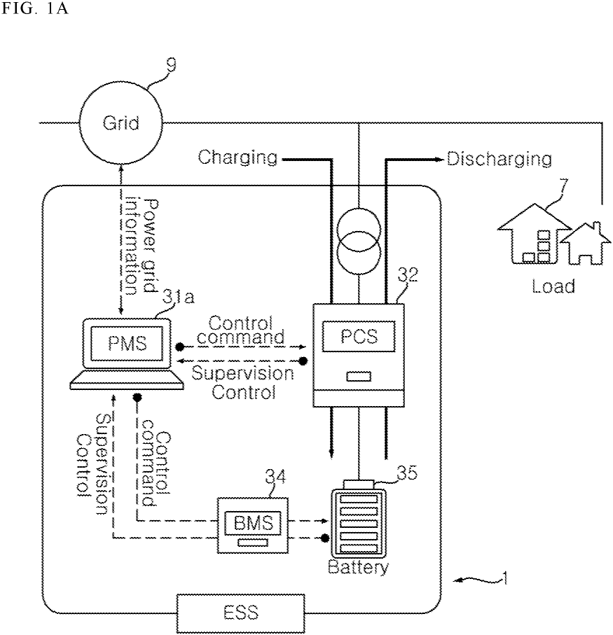

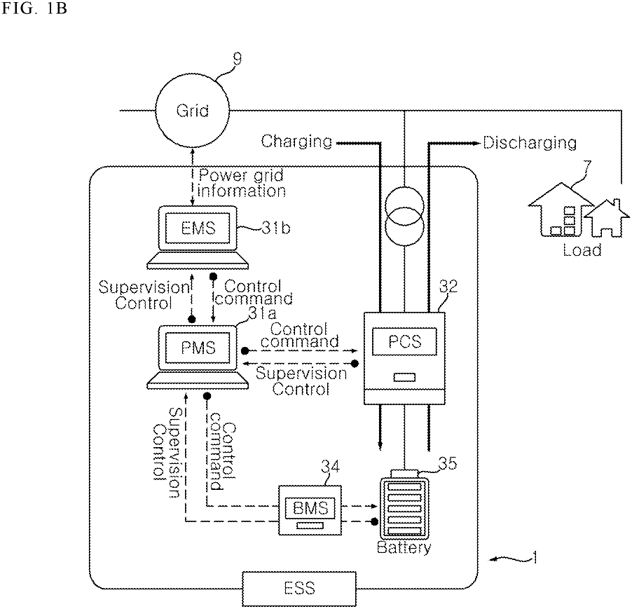

FIGS. 1A and 1B are conceptual diagrams of an energy supply system including an energy storage system according to an embodiment of the present disclosure.

Referring to FIGS. 1A and 1B, the energy supply system includes a battery-based (see, e.g., battery 35) energy storage system 1 in which electrical energy is stored, a load 7 that is a power demander (or consumer), and a grid 9 provided as an external power supply source.

The energy storage system 1 includes a battery 35 that stores (charges) the electric energy received from the grid 9, or the like in the form of direct current (DC) and/or outputs (discharges) the stored electric energy to the grid 9, or the like, a power conditioning system (PCS) 32 for converting electrical characteristics (e.g. AC/DC interconversion, frequency, voltage) for charging or discharging the battery 35, and a battery management system 34 (BMS) that monitors and manages information (or parameters) such as current, voltage, and temperature of the battery 35.

The grid 9 may include a power generation facility for generating electric power, a transmission line, and the like. The load 7 may include a home appliance such as a refrigerator, a washing machine, an air conditioner, a TV, a robot cleaner, and a robot, a mobile electronic device such as a vehicle and a drone, and the like, as a consumer that consumes power.

The energy storage system 1 may store power from outside the system 1 in the battery 35 and then output power to outside the system 1. For example, the energy storage system 1 may receive DC power or AC power from outside the system 1, store it in the battery 35, and then output the DC power or AC power to outside the system 1.

Since the battery 35 mainly stores DC power, the energy storage system 1 may receive DC power or convert the received AC power to DC power and store it in the battery 35, and may convert the DC power stored in the battery 35, and may supply the converted power to the grid 9 or the load 7.

The power conditioning system 32 in the energy storage system 1 may perform power conversion and voltage-charge the battery 35, or may supply the DC power stored in the battery 35 to the grid 9 or the load 7.

The energy storage system 1 may charge the battery 35 based on power supplied from the system and discharge the battery 35 when necessary. For example, the electric energy stored in the battery 35 may be supplied to the load 7 in an emergency such as a power outage, or at a time, date, or season when the electric energy supplied from the grid 9 is expensive.

The energy storage system 1 has the advantage of being able to improve the safety and convenience of new renewable energy generation by storing electric energy generated from a new renewable energy source such as sunlight, and to be used as an emergency power source. In addition, when the energy storage system 1 is used, it is possible to perform load leveling for a load having large fluctuations in (or over) time and season, and to save energy consumption and cost.

The battery management system 34 may measure the temperature, current, voltage, state of charge, and the like of the battery 35, and monitor the state of the battery 35. In addition, the battery management system 34 may control and manage the operating environment of the battery 35 to be optimized based on the state information of the battery 35.

The energy storage system 1 may include a power management system 31a (PMS) that controls the power conditioning system 32.

The power management system 31a may perform a function of monitoring and controlling the states of the battery 35 and the power conditioning system 32. The power management system 31a may be a controller that controls the overall operation of the energy storage system 1.

The power conditioning system 32 may control power distribution of the battery 35 according to a control command of the power management system 31a. The power conditioning system 32 may convert power according to the grid 9, a power generation means such as photovoltaic light, and the connection state of the battery 35 and the load 7.

The power management system 31a may receive state information of the battery 35 from the battery management system 34. A control command may be transmitted to the power conditioning system 32 and the battery management system 34.

The power management system 31a may include a communication means such as a Wi-Fi communication module, and a memory. Various information necessary for the operation of the energy storage system 1 may be stored in the memory. In some embodiments, the power management system 31a may include a plurality of switches and control a power supply path.

The power management system 31a and/or the battery management system 34 may calculate a state of charge (SOC) of the battery 35 using various well-known SOC calculation methods such as a coulomb counting method and a method of calculating a SOC based on an open circuit voltage (OCV). The battery 35 may overheat and irreversibly operate when the state of charge exceeds a maximum state of charge. Similarly, when the state of charge is less than or equal to the minimum state of charge, the battery may deteriorate and become unrecoverable. The power management system 31a and/or the battery management system 34 may monitor the internal temperature, the state of charge of the battery 35, and the like in real-time to control an optimal usage area and maximum input/output power.

The power management system 31a may operate under the control of an energy management system (EMS) 31b, which is an upper controller. The power management system 31a may control the energy storage system 1 by receiving a command from the energy management system 31b, and may transmit the state of the energy storage system 1 to the energy management system 31b. The energy management system 31b may be provided in the energy storage system 1 or may be provided in (or at) an upper system of the energy storage system 1.

The energy management system 31b may receive information such as charge information, power usage, and environmental information, and may control the energy storage system 1 according to the energy production, storage, and consumption patterns of user. The energy management system 31b may be provided as an operating system for monitoring and controlling the power management system 31a.

The controller for controlling the overall operation of the energy storage system 1 may include the power management system 31a and/or the energy management system 31b. In some embodiments, one of the power management system 31a or the energy management system 31b may also perform another function(s). In addition, the power management system 31a and the energy management system 31b may be integrated into one controller to be integrally provided.

The installation capacity of the energy storage system 1 varies according to the customer’s installation condition, and a plurality of power conditioning systems 32 and batteries 35 may be connected (or coupled) to expand according to a required capacity.

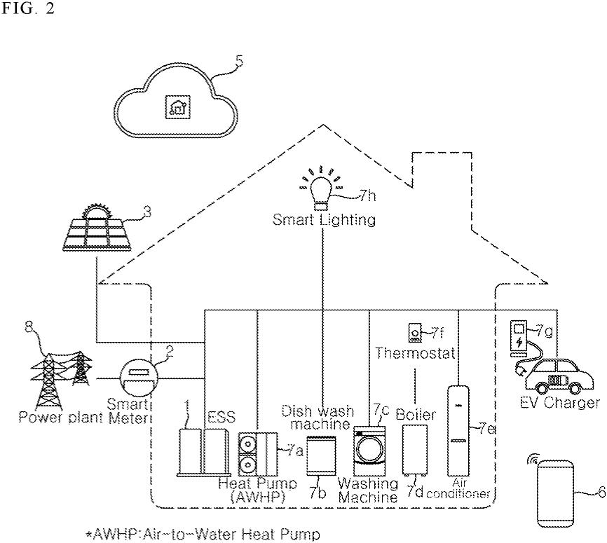

The energy storage system 1 may be connected to at least one generating plant (see generating plant 3 of FIG. 2) separately from the grid 9. A generating plant 3 may include a wind generating plant that outputs DC power, a hydroelectric generating plant that outputs DC power using hydroelectric power, a tidal generating plant that outputs DC power using tidal power, thermal generating plant that outputs DC power using heat such as geothermal heat, or the like. Hereinafter, for convenience of description, the generating plant 3 will be primarily described with reference to a photovoltaic plant (or generator).

FIG. 2 is a conceptual diagram of a home energy service system including an energy storage system according to an embodiment of the present disclosure.

The home energy service system according to an embodiment of the present disclosure may include the energy storage system 1, and may be configured as a cloud-based (see, e.g., cloud 5) intelligent energy service platform for integrated energy service management.

Referring to FIG. 2, the home energy service system is mainly implemented in a home, and may manage the supply, consumption, and storage of energy (power) in the home.

The energy storage system 1 may be connected to a grid 9 such as a power plant 8, a generating plant such as a photovoltaic generator 3, a plurality of loads 7a to 7g, and sensors (not shown) to configure a home energy service system.

The loads 7a to 7g may be a heat pump 7a, a dishwasher 7b, a washing machine 7c, a boiler 7d, an air conditioner 7e, a thermostat 7f, an electric vehicle (EV) charger 7g, a smart lighting 7h, or the like.

The home energy service system may include other loads in addition to the loads (e.g., smart devices) illustrated in FIG. 2. For example, the home energy service system may include several lights in addition to the smart lighting 7h having one or more communication modules. In addition, the home energy service system may include a home appliance that does not include a communication module.

Some of the loads 7a to 7g are set as essential loads, so that power may be supplied from the energy storage system 1 when a power outage occurs. For example, a refrigerator and at least some lighting devices may be set as essential loads that require backup in case of power failure.

The energy storage system 1 can communicate with the devices 7a to 7g, and the sensors through a short-range wireless communication module. For example, the short-range wireless communication module may be at least one of Bluetooth, Wi-Fi, or Zigbee. In addition, the energy storage system 1, the devices 7a to 7g, and the sensors may be connected to an Internet network.

The energy management system 31b may communicate with the energy storage system 1, the devices 7a to 7g, the sensors, and the cloud 5 through an Internet network, and short-range wireless communication.

The energy management system 31b and/or the cloud 5 may transmit information received from the energy storage device 1, the devices 7a to 7g, and sensors and information determined using the received information to a terminal 6. The terminal 6 may be implemented as a smart phone, a PC, a notebook computer, a tablet PC, or the like. In some embodiments, an application for controlling the operation of the home energy service system may be installed and executed in (or at) the terminal 6.

The home energy service system may include a meter 2. The meter 2 may be provided between the power grid 9 such as the power plant 8 and the energy storage system 1. The meter 2 may measure the amount of power supplied to the home from the power plant 8 and consumed. In addition, the meter 2 may be provided inside the energy storage system 1. The meter 2 may measure the amount of power discharged from the energy storage system 1. The amount of power discharged from the energy storage system 1 may include the amount of power supplied (sold) from the energy storage system 1 to the power grid 9, and the amount of power supplied from the energy storage system 1 to the devices 7a to 7g.

The energy storage system 1 may store the power supplied from the photovoltaic generator 2 and/or the power plant 8, or the residual power remaining after the supplied power is consumed.

The meter 2 may be implemented using a smart meter. The smart meter may include a communication module for transmitting information related to power usage to the cloud 5 and/or the energy management system 31b.

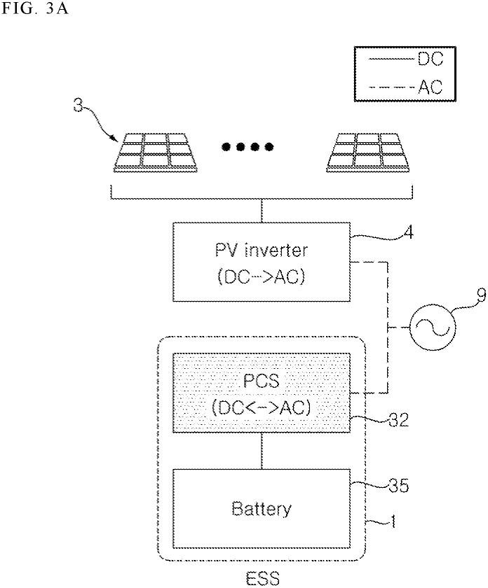

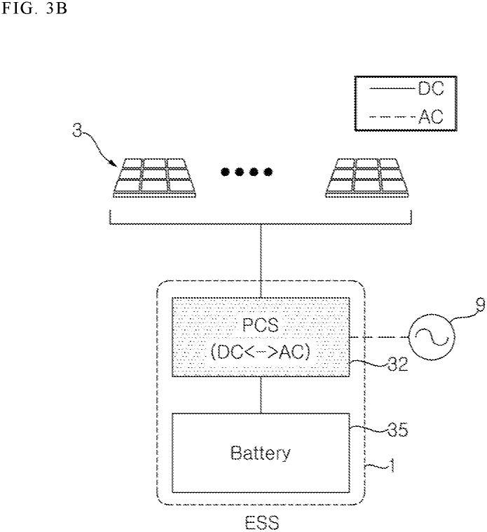

FIGS. 3A and 3B are diagrams illustrating an energy storage system installation type according to an embodiment of the present disclosure.

The home energy storage system 1 may be divided into (or categorized as) an AC-coupled energy storage system (ESS) (see FIG. 3A) and a DC-coupled ESS (see FIG. 3B) according to an installation type.

The photovoltaic plant includes a photovoltaic panel 3. Depending on the type of photovoltaic installation, the photovoltaic plant may include a photovoltaic panel 3 and a photovoltaic (PV) inverter 4 that converts DC power supplied from the photovoltaic panel 3 into AC power (see FIG. 3A). Thus, it is possible to implement the system more economically, as the energy storage system 1 independent of the existing grid 9 can be used.

In addition, according to an embodiment, the power conditioning system 32 of the energy storage system 1 and the PV inverter 4 may be implemented as an integrated power conversion device (see FIG. 3B). In this case, the DC power output from the photovoltaic panel 3 is input to the power conditioning system 32. The DC power may be transmitted to and stored in the battery 35. In addition, the power conditioning system 32 may convert DC power into AC power and supply the converted power to the grid 9. Accordingly, a more efficient system implementation can be achieved.

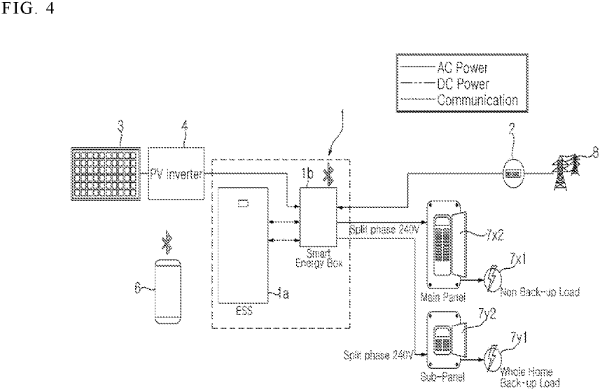

FIG. 4 is a conceptual diagram of a home energy service system including an energy storage system according to an embodiment of the present disclosure.

Referring to FIG. 4, the energy storage system 1 may be connected to the grid 9 such as the power plant 8, the power plant such as the photovoltaic generator 3, and a plurality of loads 7x1 and 7y1.

Electrical energy generated by the photovoltaic generator 3 may be converted in the PV inverter 4 and supplied to the grid 9, the energy storage system 1, and the loads 7x1 and 7y1. As described with reference to FIGS. 3A and 3B, according to the type of installation, the electrical energy generated by the photovoltaic generator 3 may be converted in the energy storage system 1, and supplied to the grid 9, the energy storage system 1, and the loads 7x1, 7y1.

The energy storage system 1 is provided with one or more wireless communication modules, and may communicate with the terminal 6. The user may monitor and control the state of the energy storage system 1 and the home energy service system through the terminal 6. In addition, the home energy service system may provide a cloud-based (see, e.g., cloud 5) service. The user may communicate with the cloud 5 through the terminal 6 regardless of location (e.g., of the user) and monitor and control the state of the home energy service system.

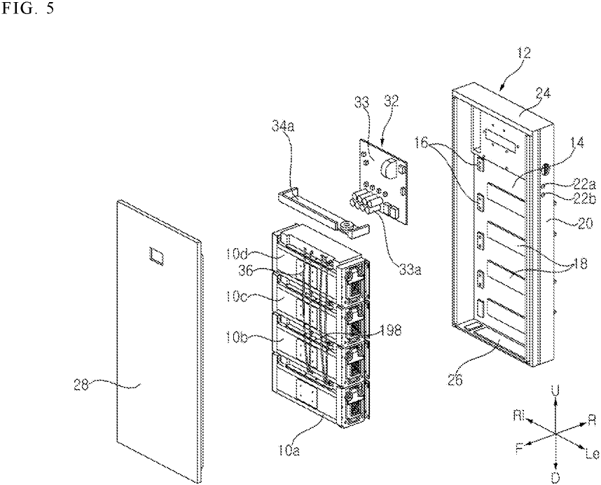

According to an embodiment of the present disclosure, the above-described battery 35, the battery management system 34, and the power conditioning system 32 may be disposed inside a casing 12 (see, e.g., FIG. 5). Since the battery 35, the battery management system 34, and the power conditioning system 32 integrated in the casing 12 can store and convert power, they may be referred to as an all-in-one energy storage system 1a.

In addition, in separate enclosures 1b outside the casing 12, a configuration for power distribution such as a power management system 31a, an auto transfer switch (ATS), a smart meter, and a switch, and a communication module for communication with the terminal 6, the cloud 5, and the like may be disposed. A configuration in which configurations related to power distribution and management are integrated in one enclosure may be referred to as a smart energy box 1b.

The above-described power management system 31a may be received (or disposed) in the smart energy box 1b. A controller for controlling the overall power supply connection of the energy storage system 1 may be disposed in the smart energy box 1b. The controller may be the above mentioned power management system 31a.

In addition, switches are received (or disposed) in the smart energy box 1b to control the connection state of the connected grid power source 8, 9, the photovoltaic generator 3, the battery 35 of all-in-one energy storage system 1a, and loads 7x1, 7y1. The loads 7x1, 7y1 may be connected to the smart energy box 1b through the load panel 7x2, 7y2.

The smart energy box 1b is connected to the grid power source 8, 9 and the photovoltaic generator 3. In addition, when a power failure occurs in the system 8, 9, the auto transfer switch (ATS), which may be disposed in the smart energy box 1b, is switched so that the electric energy which is produced by the photovoltaic generator 3 or stored in the battery 35 is supplied to a certain load 7y1.

Alternatively, the power management system 31a may perform an auto transfer switch ATS function. For example, when a power failure occurs in the system 8, 9, the power management system 31a may control a switch such as a relay so that the electrical energy that is produced by the photovoltaic generator 3 or stored in the battery 35 is transmitted to a certain load 7y1.

A current sensor, a smart meter, or the like may be disposed in each current supply path. Electric energy of the electricity produced through the energy storage system 1 and the photovoltaic generator 3 may be measured and managed by a smart meter (or at least a current sensor).

The energy storage system 1 according to an embodiment of the present disclosure includes at least an all-in-one energy storage system 1a. In addition, the energy storage system 1 according to an embodiment of the present disclosure includes the all-in-one energy storage system 1a and the smart energy box 1b, thereby providing an integrated service that can simply and efficiently perform storage, supply, distribution, communication, and control of power.

The energy storage system 1 according to an embodiment of the present disclosure may operate in a plurality of operation modes. In a PV self consumption mode, photovoltaic generation power is first used in the load, and the remaining power is stored in the energy storage system 1. For example, when more power is generated in the photovoltaic generator 3 than the amount of power used by the loads 7x1 and 7y1 during the day, the battery 35 is charged.

In a charge/discharge mode based on a rate system, four time zones may be set and input, the battery 35 may be discharged during a time period when the electric rate is expensive, and the battery 35 may be charged during a time period when the electric rate is cheap. The energy storage system 1 may help a user to save electric rate (or electricity costs) in the charge/discharge mode based on a rate system.

A backup-only mode is a mode for emergency situations such as power outages, and can operate, with the highest priority, such that when a typhoon is expected (or predicted) by a weather forecast or there is a possibility of other power outages, the battery 35 may be charged up to a maximum and supplied to an essential load 7y1 in an emergency.

The energy storage system 1 of the present disclosure will be described with reference to FIGS. 5 to 7. More particularly, detailed structures of the all-in-one energy storage system 1a are disclosed.

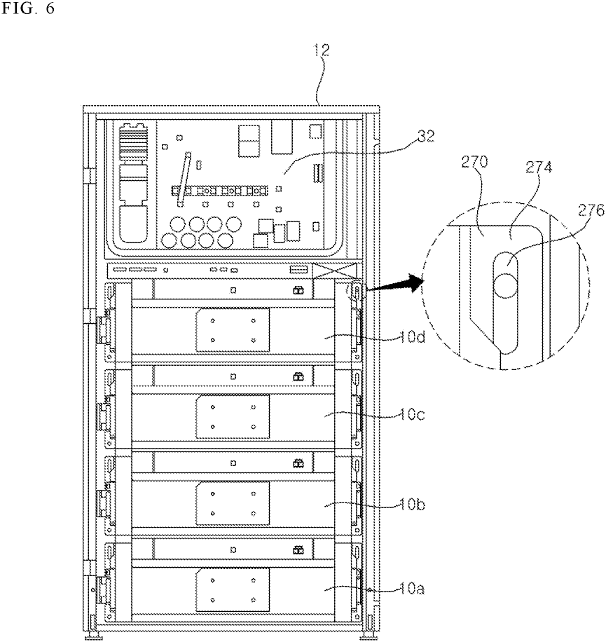

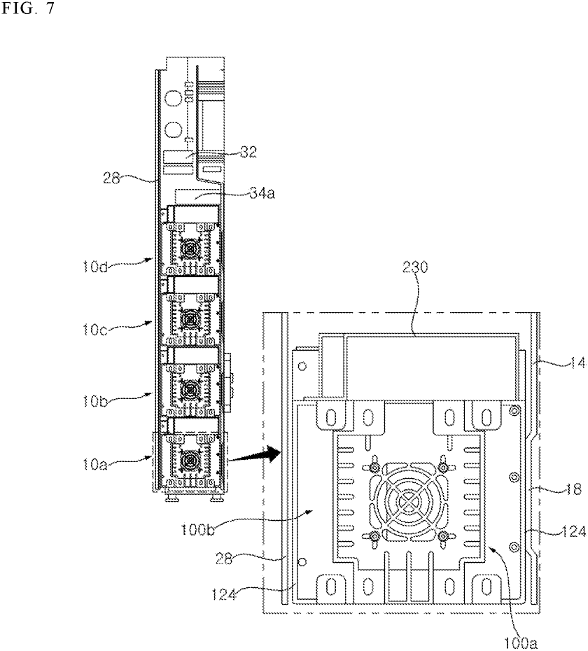

FIG. 5 is an exploded perspective view of an energy storage system including a plurality of battery packs according to an embodiment of the present disclosure, FIG. 6 is a front view of an energy storage system in a state in which a door is removed, and FIG. 7 is a cross-sectional view of one side of the energy storage system of FIG. 6.

Referring to FIG. 5, the energy storage system 1 includes at least one battery pack 10, a casing 12 forming a space in which at least one battery pack 10 is disposed, a door 28 for opening and closing the front surface (or a front) of the casing 12, a power conditioning system 32 (PCS) which is disposed inside the casing 12 and converts the characteristics of electricity so as to charge or discharge a battery, and a battery management system (BMS) that monitors information (or parameters) such as current, voltage, and temperature of the battery cell 101 (see, e.g., FIG. 10).

The casing 12 may have an open front shape. The casing 12 may include a casing rear wall 14 covering the rear, a pair of casing side walls 20 extending to the front from both side ends of the casing rear wall 14, a casing top wall 24 extending to the front from the upper end of the casing rear wall 14, and a casing base 26 extending to the front from the lower end of the casing rear wall 14. The casing rear wall 14 includes a pack fastening portion 16 formed to be fastened with the battery pack 10 and a contact plate 18 protruding to (or toward) the front to contact a heat dissipation plate 124 (see, e.g., FIG. 7) of the battery pack 10.

Referring to FIG. 5, the contact plate 18 may be disposed to protrude to the front from the casing rear wall 14. The contact plate 18 may be disposed to contact one side of the heat dissipation plate 124. Accordingly, heat emitted from the plurality of battery cells 101 disposed inside the battery pack 10 may be radiated outside through the heat dissipation plate 124 and the contact plate 18.

A switch 22a, 22b for turning on/off the power of the energy storage system 1 may be disposed in (or at) one of the pair of casing sidewalls 20. In the present disclosure, a first switch 22a and a second switch 22b are disposed to enhance the safety of the power supply or the safety of the operation of the energy storage system 1.

The power conditioning system 32 may include a circuit substrate 33 and an insulated gate bipolar transistor (IGBT) that is disposed in (or at) one side of the circuit substrate 33 and performs power conversion.

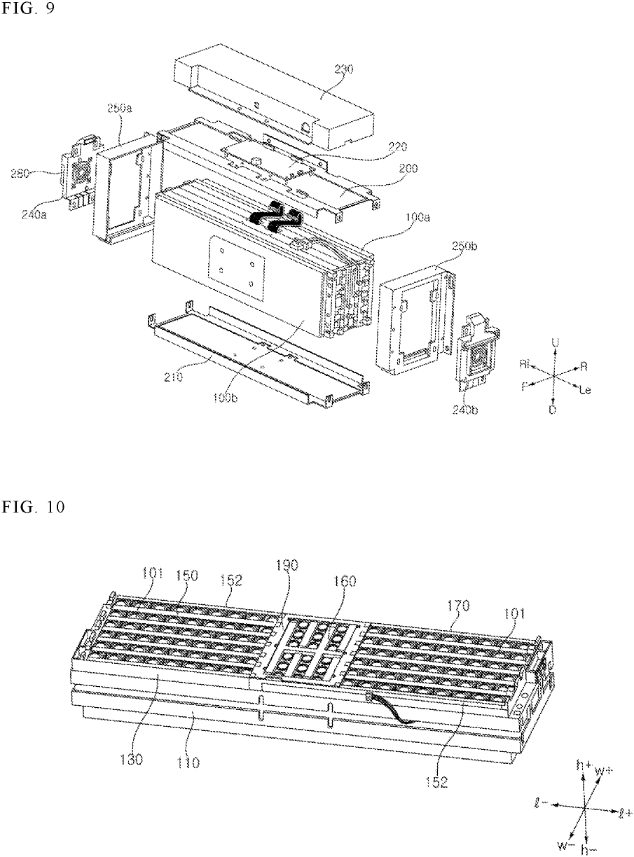

The battery monitoring system may include a battery pack circuit substrate 220 (see, e.g., FIG. 9) disposed in each of the plurality of battery packs 10a, 10b, 10c, 10d, and a main circuit substrate 34a which is disposed inside the casing 12 and connected to a plurality of battery pack circuit substrates 220 through a communication line 36.

The main circuit substrate 34a may be connected (or coupled) to the battery pack circuit substrate 220 disposed in each of the plurality of battery packs 10a, 10b, 10c, and 10d by (or via) the communication line 36. The main circuit substrate 34a may be connected to a power line 198 extending from the battery pack 10.

At least one battery pack 10a, 10b, 10c, and 10d may be disposed inside the casing 12. For example, a plurality of battery packs 10a, 10b, 10c, and 10d are disposed inside the casing 12. The plurality of battery packs 10a, 10b, 10c, and 10d may be disposed in (or along) the vertical direction.

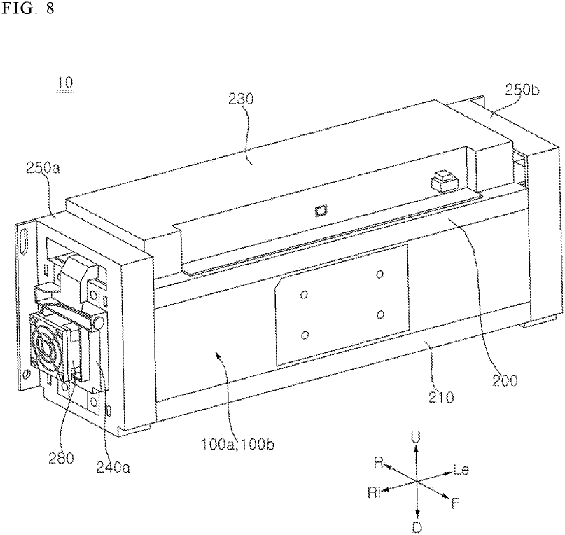

The plurality of battery packs 10a, 10b, 10c, and 10d may be disposed such that the upper end and lower end of each side bracket 250a, 250b (see, e.g., FIG. 8) contact each other. Each of the battery packs 10a, 10b, 10c, and 10d disposed vertically is disposed such that the battery module 100a, 100b and the top cover 230 do not contact each other (see, e.g., FIG. 9).

Each of the plurality of battery packs 10 is fixedly disposed in the casing 12. Each of the plurality of battery packs 10a, 10b, 10c, and 10d is fastened to the pack fastening portion 16 disposed in the casing rear wall 14. That is, the fixing bracket 270 (see, e.g., FIG. 6) of each of the plurality of battery packs 10a, 10b, 10c, and 10d is fastened to the pack fastening portion 16. The pack fastening portion 16 may be disposed to protrude to (or toward) the front from the casing rear wall 14 like (or similar to) the contact plate 18.

The contact plate 18 may be disposed to protrude to the front from the casing rear wall 14. Accordingly, the contact plate 18 may be disposed to be in contact with a heat dissipation plate 124 included in the battery pack 10.

One battery pack 10 includes two battery modules 100a and 100b. Accordingly, two heat dissipation plates 124 are disposed in one battery pack 10. One heat dissipation plate 124 included in the battery pack 10 is disposed to face the casing rear wall 14, and the other heat dissipation plate 124 is disposed to face the door 28.

One heat dissipation plate 124 is disposed to contact the contact plate 18 disposed in the casing rear wall 14, and the other heat dissipation plate 124 is disposed to be spaced apart from the door 28. The other heat dissipation plate 124 may be cooled by air flowing inside the casing 12.

FIG. 8 is a perspective view of a battery pack according to an embodiment of the present disclosure, and FIG. 9 is an exploded view of a battery pack according to an embodiment of the present disclosure.

The energy storage system of the present disclosure may include a battery pack 10 in which a plurality of battery cells 101 are connected in series and in parallel. The energy storage system may include a plurality of battery packs 10a, 10b, 10c, and 10d (refer to FIG. 5).

First, a configuration of one battery pack 10 will be described with reference to FIGS. 8 to 9. The battery pack 10 includes at least one battery module 100a, 100b at which a plurality of battery cells 101 are connected in series and parallel, an upper fixing bracket 200 which is disposed in (or at) an upper portion of the battery module 100a, 100b and fixes the disposition (or positioning) of the battery module 100a, 100b, a lower fixing bracket 210 which is disposed in (or at) a lower portion of the battery module 100a, 100b and fixes the disposition of the battery modules 100a and 100b, a pair of side brackets 250a, 250b which are disposed in (or at) side surfaces of the battery module 100a, 100b and fixes the disposition of the battery module 100a, 100b, a pair of side covers 240a, 240b which are disposed in (or at) side surfaces of the battery module 100a, 100b, and in which a cooling hole 242a is formed, a cooling fan 280 which is disposed in one side surface of the battery module 100a, 100b and forms an air flow inside the battery module 100a, 100b, a battery pack circuit substrate 220 which is disposed in (or at) the upper side of the upper fixing bracket 200 and collects sensing information of the battery module 100a, 100b, and a top cover 230 which is disposed in (or at) the upper side of the upper fixing bracket 200 and covers the upper side of the battery pack circuit substrate 220.

The battery pack 10 includes at least one battery module 100a, 100b. Referring to FIG. 9, the battery pack 10 of the present disclosure includes a battery module assembly 100 configured of two battery modules 100a, 100b which are electrically connected (or coupled) to each other and physically fixed. The battery module assembly 100 includes a first battery module 100a and a second battery module 100b disposed to face each other.

FIG. 10 is a perspective view of a battery module according to an embodiment of the present disclosure and FIG. 11 is an exploded view of a battery module according to an embodiment of the present disclosure.

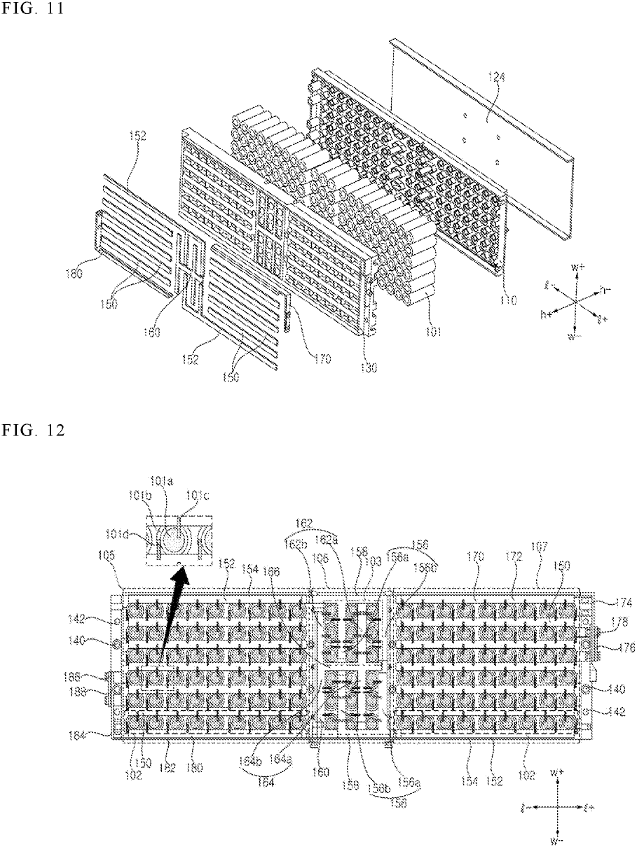

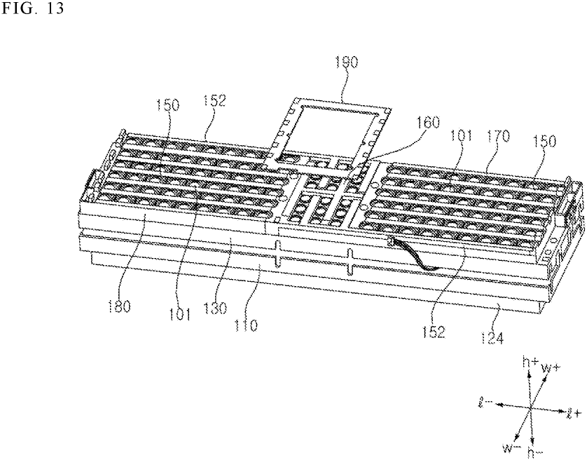

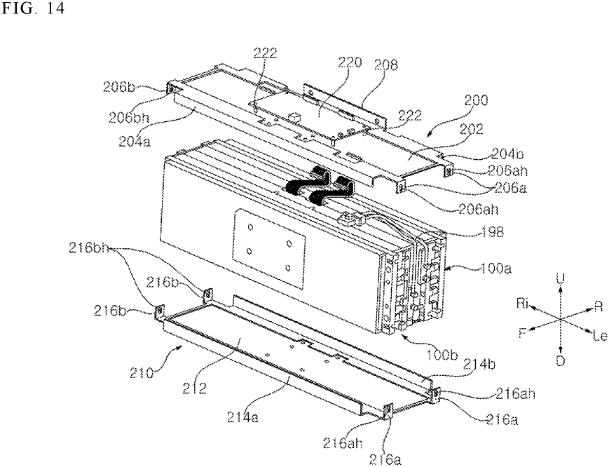

FIG. 12 is a front view of a battery module according to an embodiment of the present disclosure and FIG. 13 is an exploded perspective view of a battery module and a sensing substrate according to an embodiment of the present disclosure.

Hereinafter, the first battery module 100a of the present disclosure will be described with reference to FIGS. 10 to 13. The configuration and shape of the first battery module 100a described below may also be applied (or applicable) to the second battery module 100b.

The battery module described in FIGS. 10 to 13 may be described with reference to a vertical direction based on the height direction (h+, h-) of the battery module. The battery module described in FIGS. 10 to 13 may be described with reference to the left-right direction based on the length direction (1+, 1-) of the battery module. The battery module described in FIGS. 10 to 13 may be described with reference to the front-rear direction based on the width direction (w+, w-) of the battery module. The direction setting of the battery module used in FIGS. 10 to 13 may be different from the direction setting in a structure of the battery pack 10 described with reference to other drawings. In the battery module described in FIGS. 10 to 13, the width direction (w+, w-) of the battery module may be described as a first direction, and the length direction (1+, 1-) of the battery module may be described as a second direction.

The first battery module 100a includes a plurality of battery cells 101, a first frame 110 for fixing the lower portion of the plurality of battery cells 101, a second frame 130 for fixing the upper portion of the plurality of battery cells 101, a heat dissipation plate 124 which is disposed in (or at) the lower side of the first frame 110 and dissipates heat generated from the battery cell 101, a plurality of bus bars which are disposed in (or at) the upper side of the second frame 130 and electrically connect the plurality of battery cells 101, and a sensing substrate 190 which is disposed in (or at) the upper side of the second frame 130 and detects information of the plurality of battery cells 101.

The first frame 110 and the second frame 130 may fix the disposition (or positioning) of the plurality of battery cells 101. In the first frame 110 and the second frame 130, the plurality of battery cells 101 are disposed to be spaced apart from each other. Since the plurality of battery cells 101 are spaced apart from each other, air may flow into a space between the plurality of battery cells 101 by the operation of the cooling fan 280 described below.

The first frame 110 fixes the lower end of the battery cell 101. The first frame 110 includes a lower plate 112 having a plurality of battery cell holes 112a formed therein, a first fixing protrusion 114 which protrudes upward from the upper surface of the lower plate 112 and fixes the disposition of the battery cell 101, a pair of first sidewalls 116 which protrudes upward from both ends of the lower plate 112, and a pair of first end walls 118 which protrudes upward from both ends of the lower plate 112 and connects both ends of the pair of first side walls 116.

The pair of first sidewalls 116 may be disposed parallel to a first cell array 102 described below. The pair of first end walls 118 may be disposed perpendicular to the pair of first side walls 116.

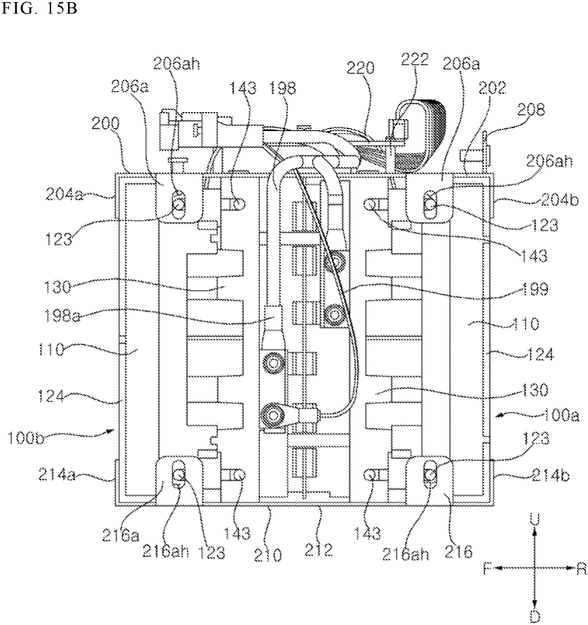

Referring to FIG. 13, the first frame 110 includes a first fastening protrusion 120 protruding to be fastened to the second frame 130, and a module fastening protrusion 122 protruding to be fastened with the first frame 110 included in the second battery module 100b disposed adjacently. A frame screw 125 for fastening the second frame 130 and the first frame 110 is disposed in the first fastening protrusion 120. A module screw 194 (see, e.g., FIG. 15A) for fastening the first battery module 100a and the second battery module 100b is disposed in the module fastening protrusion 122. The frame screw 125 fastens the second frame 130 and the first frame 110. The frame screw 125 may fix the disposition of the plurality of battery cells 101 by fastening the second frame 130 and the first frame 110.

The plurality of battery cells 101 are fixedly disposed in the second frame 130 and the first frame 110. A plurality of battery cells 101 are disposed in series and in parallel. The plurality of battery cells 101 are fixedly disposed by a first fixing protrusion 114 of the first frame 110 and a second fixing protrusion 134 of the second frame 130.

Referring to FIG. 12, the plurality of battery cells 101 are spaced apart from each other in (or along) the length direction (1+, 1-) and the width direction (w+, w-) of the battery module.

The plurality of battery cells 101 includes a cell array connected in parallel to one bus bar. The cell array may refer to a set electrically connected in parallel to one bus bar.

The first battery module 100a may include a plurality of cell arrays 102 and 103 electrically connected in series. The plurality of cell arrays 102 and 103 are electrically connected to each other in series. The first battery module 100a has a plurality of cell arrays 102 and 103 connected in series.

The plurality of cell arrays 102 and 103 may include a first cell array 102 in which a plurality of battery cells 101 are disposed in (or along) a straight line, and a second cell array 103 in which a plurality of cell array rows and columns are disposed.

The first battery module 100a may include a first cell array 102 in which a plurality of battery cells 101 are disposed in (or along) a straight line, and a second cell array 103 in which a plurality of rows and columns are disposed.

Referring to FIG. 12, in the first cell array 102, a plurality of battery cells 101 are disposed in (or at) the left and right side in (or along) the length direction (1+, 1-) of the first battery module 100a. The plurality of first cell arrays 102 are disposed in (or at) the front and rear side in (or along) the width direction (w+, w-) of the first battery module 100a.

Referring to FIG. 12, the second cell array 103 includes a plurality of battery cells 101 spaced apart from each other in the width direction (w+, w-) and the length direction (1+, 1-) of the first battery module 100a.

The first battery module 100a includes a first cell group 105 in which a plurality of first cell arrays 102 are disposed in parallel, and a second cell group 106 that includes at least one second cell array 103 and is disposed in (or at) one side of the first cell group 105.

The first battery module 100a includes a first cell group 105 in which a plurality of first cell arrays 102 are connected in series, and a third cell group 107 in which a plurality of first cell arrays 102 are connected in series, and which are spaced apart from the first cell group 105. The second cell group is disposed between the first cell group 105 and the third cell group 107.

In the first cell group 105, a plurality of first cell arrays 102 are connected in series. In the first cell group 105, a plurality of first cell arrays 102 are spaced apart from each other in (or along) the width direction of the battery module. The plurality of first cell arrays 102 included in the first cell group 105 are spaced apart in (or along) a direction perpendicular to the direction in which the plurality of battery cells 101 included in each of the first cell arrays 102 are disposed.

Referring to FIG. 12, nine battery cells 101 connected in parallel are disposed in each of the first cell array 102 and the second cell array 103. Referring to FIG. 12, in the first cell array 102, nine battery cells 101 are spaced apart from each other in (or along) the length direction of the battery module. In the second cell array 103, nine battery cells are spaced apart from each other in a plurality of rows and a plurality of columns. Referring to FIG. 12, in the second cell array 103, three battery cells 101 that are spaced apart from each other in (or along) the width direction of the battery module are spaced apart from each other in the length direction of the battery module. Here, the length direction (1+, 1-) of the battery module may be set as (or may refer to) a column direction, and the width direction (w+, w-) of the battery module may be set as (or may refer to) a row direction.

Referring to FIG. 12, each of the first cell group 105 and the third cell group 107 is disposed such that six first cell arrays 102 are connected in series. In each of the first cell group 105 and the third cell group 107, six first cell arrays 102 are spaced apart from each other in (or along) the width direction of the battery module.

Referring to FIG. 12, the second cell group 106 includes two second cell arrays 103. The two second cell arrays 103 are spaced apart from each other in (or along) the width direction of the battery module. The two second cell arrays 103 are connected in parallel to each other. Each of the two second cell arrays 103 is disposed symmetrically with respect to the horizontal bar 166 of a third bus bar 160 described below.

The first battery module 100a includes a plurality of bus bars which are disposed between the plurality of battery cells 101, and electrically connect the plurality of battery cells 101. Each of the plurality of bus bars connects in parallel the plurality of battery cells included in a cell array disposed adjacent to each other. Each of the plurality of bus bars may connect in series two cell arrays disposed adjacent to each other.

The plurality of bus bars includes a first bus bar 150 connecting the two first cell arrays 102 in series, a second bus bar 152 connecting the first cell array 102 and the second cell array 103 in series, and a third bus bar 160 connecting the two second cell arrays 103 in series.

The plurality of bus bars include a fourth bus bar 170 connected to one first cell array 102 in series. The plurality of bus bars include a fourth bus bar 170 which is connected to one first cell array 102 in series and connected to the other battery module 100b included in the same battery pack 10, and a fifth bus bar 180 which is connected to one first cell array 102 in series and connected to one battery module included in the other battery pack 10. The fourth bus bar 170 and the fifth bus bar 180 may have the same shape.

The first bus bar 150 is disposed between two first cell arrays 102 spaced apart from each other in (or along) the length direction of the battery module. The first bus bar 150 connects in parallel a plurality of battery cells 101 included in one first cell array 102. The first bus bar 150 connects in series the two first cell arrays 102 disposed in (or along) the length direction (1+, 1-) of the battery module.

Referring to FIG. 12, the first bus bar 150 is electrically connected to a positive terminal 101a of each of the battery cells 101 of the first cell array 102 which is disposed in (or at) the front in (or along) the width direction (w+, w-) of the battery module, and the first bus bar 150 is electrically connected to a negative terminal 101b of each of the battery cells 101 of the first cell array 102 which is disposed in (or at) the rear in (or along) the width direction (w+, w-) of the battery module.

Referring to FIG. 12, in the battery cell 101, the positive terminal 101a and the negative terminal 101b are partitioned in (or at) the upper end thereof. In the battery cell 101, the positive terminal 101a is disposed in (or at) the center of a top surface formed in a circle, and the negative terminal 101b is disposed in (or at) the circumference portion of the positive terminal 101a. Each of the plurality of battery cells 101 may be connected to each of the plurality of bus bars through a cell connector 101c, 101d.

The first bus bar 150 has a straight bar shape. The first bus bar 150 is disposed between the two first cell arrays 102. The first bus bar 150 is connected to the positive terminal of the plurality of battery cells 101 included in the first cell array 102 disposed in one side, and is connected to the negative terminal of the plurality of battery cells 101 included in the first cell array 102 disposed in the other side.

The first bus bar 150 is disposed between the plurality of first cell arrays 102 disposed in the first cell group 105 and the third cell group 107.

The second bus bar 152 connects the first cell array 102 and the second cell array 103 in series. The second bus bar 152 includes a first connecting bar 154 connected to the first cell array 102 and a second connecting bar 156 connected to the second cell array 103. The second bus bar 152 is disposed perpendicular to the first connecting bar 154. The second bus bar 152 includes an extension portion 158 that extends from the first connecting bar 154 and is connected to the second connecting bar 156.

The first connecting bar 154 may be connected to different electrode terminals of the second connecting bar 156 and the battery cell. Referring to FIG. 12, the first connecting bar 154 is connected to the positive terminal 101a of the battery cell 101 included in the first cell array 102, and the second connecting bar 156 is connected to the negative terminal 101b of the battery cell 101 included in the second cell array 103. However, this is in reference to one embodiment, and it is possible for the connecting bars 154, 156 to be connected to an opposite electrode terminal.

The first connecting bar 154 is disposed in (or at) one side of the first cell array 102. The first connecting bar 154 has a straight bar shape extending in (or along) the length direction of the battery module. The extension portion 158 has a straight bar shape extending in (or along) the direction in which the first connecting bar 154 extends.

The second connecting bar 156 is disposed perpendicular to the first connecting bar 154. The second connecting bar 156 has a straight bar shape extending in (or along) the width direction (w+, w-) of the battery module. The second connecting bar 156 may be disposed in (or at) one side of the plurality of battery cells 101 included in the second cell array 103. The second connecting bar 156 may be disposed between the plurality of battery cells 101 included in the second cell array 103. The second connecting bar 156 extends in (or along) the width direction (w+, w-) of the battery module, and is connected to the battery cell 101 disposed in (or at) one side or both sides.

The second connecting bar 156 includes a connecting bar 156a and a connecting bar 156b spaced apart from the connecting bar 156a. The connecting bar 156a is disposed between the plurality of battery cells 101, and the connecting bar 156b is disposed in (or at) one side of the plurality of battery cells 101.

The third bus bar 160 connects in series the two second cell arrays 103 spaced apart from each other. The third bus bar 160 includes a first vertical bar 162 connected to one cell array among the plurality of second cell arrays 103, a second vertical bar 164 connected to the other cell array among the plurality of second cell arrays 103, and a horizontal bar 166 which is disposed between the plurality of second cell arrays 103 and connected to the first vertical bar 162 and the second vertical bar 164. The first vertical bar 162 and the second vertical bar 164 may be symmetrically disposed with respect to the horizontal bar 166.

A plurality of second vertical bars 164 may be disposed to be spaced apart from each other in (or along) the length direction (1+, 1-) of the battery module. Referring to FIG. 12, a vertical bar 164a, and a vertical bar 164b which is spaced apart from the vertical bar 164a in (or along) the length direction of the battery module may be included.

The first vertical bar 162 or the second vertical bar 164 may be disposed parallel to the second connecting bar 156 of the second bus bar 152. The battery cell 101 included in the second cell array 103 may be disposed between the first vertical bar 162 and the second connecting bar 156. Similarly, the battery cell 101 included in the second cell array 103 may be disposed between the second vertical bar 164 and the second connecting bar 156.

The first battery module 100a includes a fourth bus bar 170 connected to the second battery module 100b included in the same battery pack 10, and a fifth bus bar 180 connected to a battery module included in another battery pack 10.

The fourth bus bar 170 is connected to the second battery module 100b which is another battery module included in the same battery pack 10. That is, the fourth bus bar 170 is connected to the second battery module 100b included in the same battery pack 10 through a high current bus bar 196 (see, e.g., FIG. 15A) described below.

The fifth bus bar 180 is connected to another battery pack 10. That is, the fifth bus bar 180 may be connected to a battery module included in another battery pack 10 through a power line 198 described below.

The fourth bus bar 170 includes a cell connecting bar 172 which is disposed in one side of the first cell array 102, and connects in parallel the plurality of battery cells 101 included in the first cell array 102, and an additional connecting bar 174 which is vertically bent from the cell connecting bar 172 and extends along the end wall of the second frame 130.

The cell connecting bar 172 is disposed in (or at) the second sidewall 136 of the second frame 130. The cell connecting bar 172 may be disposed to surround a portion of the outer circumference of the second sidewall 136. The additional connecting bar 174 is disposed outside the second end wall 138 of the second frame 130.

The additional connecting bar 174 includes a connecting hanger 176 to which the high current bus bar 196 is connected. The connecting hanger 176 is provided with a groove 178 opened upward. The high current bus bar 196 may be seated on the connecting hanger 176 through the groove 178. The high current bus bar 196 may be fixedly disposed in the connecting hanger 176 through a separate fastening screw while seated on the connecting hanger 176.

The fifth bus bar 180 may have the same configuration and shape as the fourth bus bar. That is, the fifth bus bar 180 includes a cell connecting bar 182 and an additional connecting bar 184. The additional connecting bar 184 of the fifth bus bar 180 includes a connecting hanger 186 to which a terminal 198a of the power line 198 is connected. The connecting hanger 186 is provided with a groove 188 into which the terminal 198a of the power line 198 is inserted.

The sensing substrate 190 is electrically connected to a plurality of bus bars disposed inside the first battery module 100a. The sensing substrate 190 may be electrically connected to each of the plurality of first bus bars 150, the plurality of second bus bars 152, the third bus bar 160, and the plurality of fourth bus bars 170. The sensing substrate 190 is connected to each of the plurality of bus bars, so that information such as voltage and current values of the plurality of battery cells 101 included in the plurality of cell arrays can be obtained.

The sensing substrate 190 may have a rectangular ring shape. The sensing substrate 190 may be disposed between the first cell group 105 and the third cell group 107. The sensing substrate 190 may be disposed to surround the second cell group 106. The sensing substrate 190 may be disposed to partially overlap the second bus bar 152.

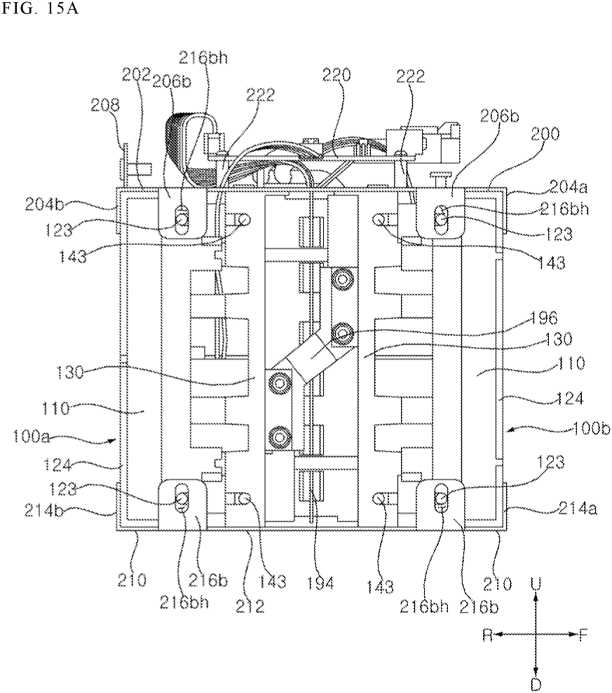

FIG. 14 is a perspective view of a battery module and a battery pack circuit substrate according to an embodiment of the present disclosure, FIG. 15A is a side view of the battery module and the battery pack circuit substrate of FIG. 14 in a coupled state, and FIG. 15B is another side view of the battery module and the battery pack circuit substrate of FIG. 14 in a coupled state.

Referring to FIG. 14 to 15B, the battery pack 10 includes an upper fixing bracket 200 which is disposed in (or at) an upper portion of the battery module 100a, 100b and fixes the battery module 100a, 100b, a lower fixing bracket 210 which is disposed in (or at) a lower portion of the battery module 100a, 100b and fixes the battery modules 100a and 100b, a battery pack circuit substrate 220 which is disposed in (or at) an upper side of the upper fixing bracket 200 and collects sensing information of the battery module 100a, 100b, and a spacer 222 which separates the battery pack circuit substrate 220 from the upper fixing bracket 200.

The upper fixing bracket 200 is disposed in (or at) an upper side of the battery module 100a, 100b. The upper fixing bracket 200 includes an upper board 202 that covers at least a portion of the upper side of the battery module 100a, 100b, a first upper holder 204a which is bent downward from the front end of the upper board 202 and disposed to be in contact with the front portion of the battery module 100a, 100b, a second upper holder 204b which is bent downward from the rear end of the upper board 202 and disposed to be in contact with the rear portion of the battery module 100a, 100b, a first upper mounter 206a which is bent downward from a side end of the upper board 202 and coupled to a side of the battery module 100a, 100b, a second upper mounter 206b which is bent downward from the other side end of the upper board 202 and coupled to the other side of the battery module 100a, 100b, and a rear bender 208 which is bent upward from the rear end of the upper board 202.

The upper board 202 is disposed in (or at) the upper side of the battery module 100a, 100b. Each of the first upper mounter 206a and the second upper mounter 206b is disposed to surround the front and rear of the battery module 100a, 100b. Accordingly, the first upper mounter 206a and the second upper mounter 206b may maintain a state in which the first battery module 100a and the second battery module 100b are coupled.

A pair of first upper mounters 206a spaced apart in the front-rear direction are disposed in (or at) one side end of the upper board 202. A pair of second upper mounters 206b spaced apart in the front-rear direction are disposed in (or at) the other side end of the upper board 202.

The pair of first upper mounters 206a are coupled to the first fastening hole 123 (see, e.g., FIG. 15A) formed in the first battery module 100a and the second battery module 100b. In each of the pair of first upper mounters 206a, a first upper mounter hole 206ah is formed in a position corresponding to the first fastening hole 123. Similarly, the pair of second upper mounters 206b are coupled to the first fastening hole 123 formed in the first battery module 100a and the second battery module 100b, and a second upper mounter hole 206bh is formed in a position corresponding to the first fastening hole 123.

The position of the upper fixing bracket 200 can be fixed in (or at) the upper side of the battery module 100a, 100b by the first upper holder 204a, the second upper holder 204b, the first upper mounter 206a, and the second upper mounter 206b. That is, due to the above structure, the upper fixing bracket 200 can maintain the structure of the battery module 100a, 100b.

The upper fixing bracket 200 is fixed to the first frame 110 of each of the first battery module 100a and the second battery module 100b. Each of the first upper mounter 206a and the second upper mounter 206b of the upper fixing bracket 200 is fixed to the first fastening hole 123 formed in the first frame 110 of each of the first battery module 100a and the second battery module 100b.

The rear bender 208 may fix a top cover 230 described below. The rear bender 208 may be fixed to a rear wall 234 of the top cover 230. The rear bender 208 may limit the rear movement of the top cover 230. Accordingly, it is possible to facilitate fastening of the top cover 230 and the upper fixing bracket 200.

The lower fixing bracket 210 is disposed in (or at) the lower side of the battery module 100a, 100b. The lower fixing bracket 210 includes a lower board 212 that covers at least a portion of the lower portion of the battery module 100a, 100b, a first lower holder 214a which is bent upward from the front end of the lower board 212 and disposed to be in contact with the front portion of the battery module 100a, 100b, a second lower holder 214b which is bent upward from the rear end of the lower board 212 and disposed to be in contact with the rear portion of the battery module 100a, 100b, a first lower mounter 216a which is bent upward from a side end of the lower board 212 and coupled to a side of the battery module 100a, 100b, and a second lower mounter 216b which is bent upward from the other side end of the lower board 212 and coupled to the other side of the battery module 100.

Each of the first lower mounter 216a and the second lower mounter 216b is disposed to surround the front and rear of the battery module 100a, 100b. Accordingly, the first lower mounter 216a and the second lower mounter 216b may maintain a state in which the first battery module 100a and the second battery module 100b are coupled.

A pair of first lower mounters 216a spaced apart in the front-rear direction are disposed in (or at) one side end of the lower board 212. A pair of second lower mounters 216b spaced apart in the front-rear direction are disposed in (or at) the other side end of the lower board 212.

The pair of first lower mounters 216a are coupled to the first fastening hole 123 formed in the first battery module 100a and the second battery module 100b. In each of the pair of first lower mounters 216a, a first lower mounter hole 216ah is formed in a position corresponding to the first fastening hole 123. Similarly, the pair of second lower mounters 216b are coupled to the first fastening hole 123 formed in the first battery module 100a and the second battery module 100b, and a second lower mounter hole 216bh is formed in a position corresponding to the first fastening hole 123.

The lower fixing bracket 210 is fixed to the first frame 110 of each of the first battery module 100a and the second battery module 100b. Each of the first lower mounter 216a and the second lower mounter 216b of the lower fixing bracket 210 is fixed to the first fastening hole 123 formed in the first frame 110 of each of the first battery module 100a and the second battery module 100b.

The battery pack circuit substrate 220 may be fixedly disposed in (or at) the upper side of the upper fixing bracket 200. The battery pack circuit substrate 220 is connected to the sensing substrate 190, the bus bar, or a thermistor 224 described below to receive information of a plurality of battery cells 101 disposed inside the battery pack 10. The battery pack circuit substrate 220 may transmit information of the plurality of battery cells 101 to the main circuit substrate 34a described below.

The battery pack circuit substrate 220 may be spaced apart from the upper fixing bracket 200 to be above the upper fixing bracket 200. A plurality of spacers 222 are disposed, between the battery pack circuit substrate 220 and the upper fixing bracket 200, to space the battery pack circuit substrate 220 upward from (e.g., to be above) the upper fixing bracket 200. The plurality of spacers 222 may be disposed in (or at) an edge portion of the battery pack circuit substrate 220.

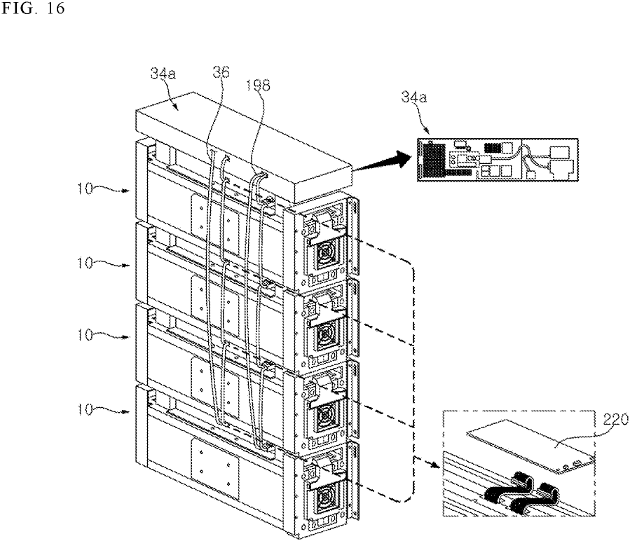

FIG. 16 is a diagram illustrating a connection between the battery pack and the battery management system according to an embodiment of the present disclosure.

Referring to FIG. 16, the battery 35 that stores received electrical energy in DC form or outputs the stored electrical energy may include a plurality of battery packs 10. Each battery pack 10 includes a plurality of battery cells 101 connected in series and in parallel.

The battery pack 10 may include battery modules 100a and 100b in which the plurality of battery cells 101 are connected in series and in parallel, and the battery modules 100a and 100b may be electrically connected to each other.

The battery cells 101 may be connected in series to increase voltage, and may be connected in parallel to increase capacity. In order to increase both the voltage and the capacity, the battery cells 101 may be connected in series and parallel.

The battery management system 34 for monitoring the state information of the battery 35 includes battery pack circuit boards 220 which are disposed in each of the plurality of battery packs 10, and obtain state information of the plurality of battery cells 101 included in each battery pack 10, and a main circuit board 34a which is connected (or coupled) to the battery pack circuit boards 220 by (or via) a communication line 36, and receives the state information obtained from each battery pack 10 from the battery pack circuit boards 220.

The energy storage system 1 according to an embodiment of the present disclosure includes the battery 35 that stores the received electrical energy in the form of direct current, or outputs the stored electrical energy, the power conditioning system 32 for converting an electrical characteristic so as to charge or discharge the battery 35, and the battery management system 34 for monitoring the state information of the battery 35. The battery 35 includes a plurality of battery packs 10 respectively including a plurality of battery cells 101, and the battery management system 34 includes battery pack circuit boards 220 which are disposed in each of the plurality of battery packs 10 and obtain state information of a plurality of battery cells 101 included in each battery pack 10, and a main circuit board 34a which is connected to the battery pack circuit boards 220 by (or via) a communication line 36 and receives state information obtained from each battery pack 10 from the battery pack circuit boards 220.

According to an embodiment of the present disclosure, by separately designing the control circuit 34a including a configuration for managing the battery 35 (particularly a configuration for safety control) from (or relative to) the battery cell sensing circuit (of the battery pack circuit boards 220), it is possible to perform the main function of the battery management system 34 and protect the control circuit 34a that manages the plurality of battery packs 10.

In the battery management system 34, a circuit composed of main components including a microcomputer unit (or microcomputer) 1780 among circuits for safety control may be separately configured. For example, when four battery packs 10 are configured to be connected, the battery management system 34 may be designed with one control circuit unit block 34a including the microcomputer unit 1780, and four battery unit blocks 220.

When the battery pack 10 is short-circuited due to an internal problem, the battery unit block 220 directly connected to the battery cell 101 may be damaged. However, the safety control circuit 34a is designed independently and can be protected without damage.

In addition, since the control circuit 34a and the battery cell sensing circuit (of the battery pack circuit boards 220) are separately configured, each circuit board 34a, 220 can be made to be smaller in size.

The state information transmitted from the battery pack circuit boards 220 to the main circuit board 34a may include at least one of current data, voltage data, or temperature data. In addition, some of the state information may be measured by a sensor mounted in the main circuit board 34a.

The battery pack circuit boards 220 are sensing and interface boards for sensing voltage, current, and temperature of the battery cells 101. In the battery pack circuit boards 220, a component for obtaining voltage, current, and temperature data of a plurality of battery cells 101 and an interface component for transmitting the obtained data to the main circuit board 34a may be mounted. The voltage, current, and temperature data of the plurality of battery cells 101 may be directly obtained from a sensor mounted in the battery pack circuit boards 220, or may be transmitted to the battery pack circuit substrates (or boards) 220 from a sensor disposed in (or at) the battery cell 101.

The plurality of battery packs 10 are connected in series by the power line 198. The power line 198 is connected to the main circuit board 34a. That is, the plurality of battery packs 10 and the main circuit board 34a are connected by the power line 198, and the voltages of the plurality of battery packs 10 are combined and applied to the main circuit board 34a. For example, a plurality of 4 kWh battery packs may be connected in series and disposed inside the casing 12. Two 4 kWh battery packs 10 may be connected to implement a total of 8 kWh combined, three 4 kWh battery packs 10 may be connected to implement a total of 12 kWh combined, and four 4 kWh battery packs 10 may be connected to implement a total of 16 kWh combined.

Two battery modules 100a and 100b may be combined to form a battery module assembly 100, and the battery pack circuit board 220 may be disposed in (or at) an upper portion of the battery module assembly 100.

The power conditioning system 32 for converting electrical characteristics for charging or discharging the battery 35 may be disposed in (or at) the upper side of the main circuit board 34a.

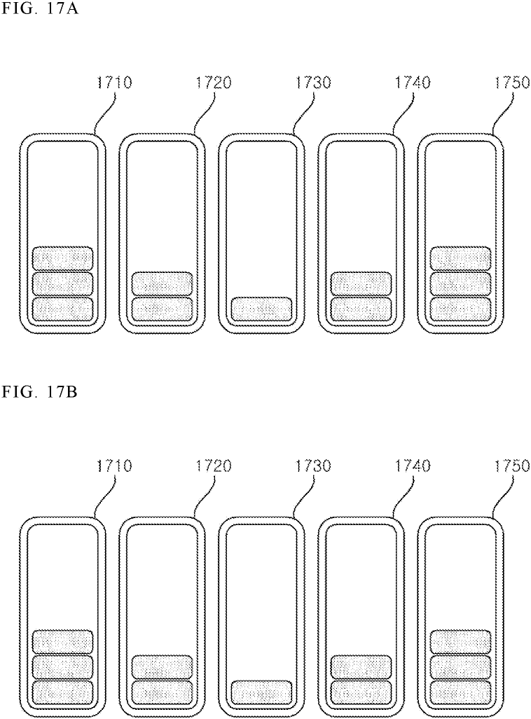

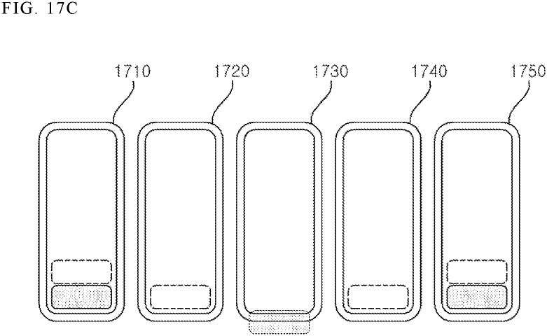

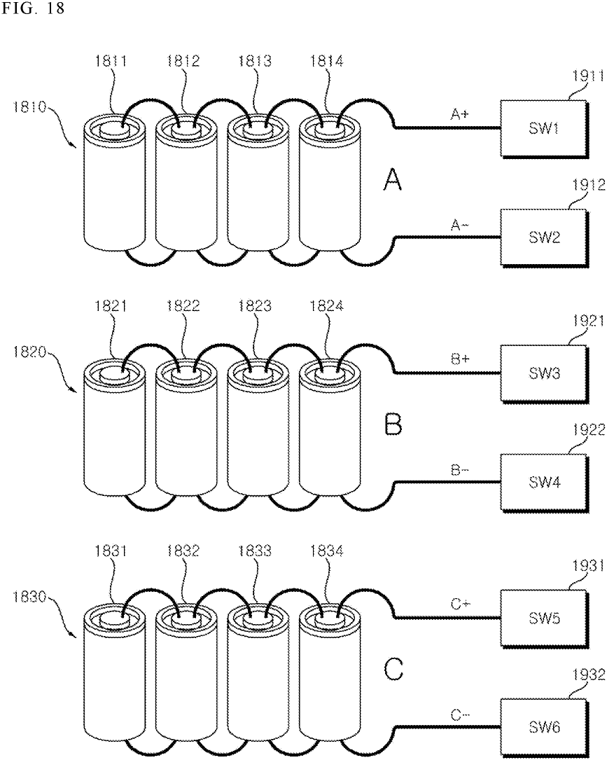

FIGS. 17A to 17C are diagrams illustrating a battery imbalance.

FIG. 17A illustrates an initial state of a battery.

The capacity of the battery is naturally decreased as time is elapsed. Therefore, the minimum capacity is guaranteed within a certain period based on the natural decrease rate. When a fresh-cell and a three-month/six-month/nine-month old or a one-year old cell are mixed and used, an imbalance state may be created as shown in FIG. 17A. Referring to FIG. 17A, the capacities of a second battery cell 1720 and a fourth battery cell 1740 are lower than the capacities of a first battery cell 1710 and a fifth battery cell 1750, and higher than the capacity of the third battery cell 1730.

When a plurality of battery cells 1710, 1720, 1730, 1740, and 1750 are connected in series, an imbalance phenomenon becomes more prominent, and thus, to address this phenomenon, they can be connected in parallel.

More preferably, at least five or more battery cells 1710, 1720, 1730, 1740, 1750 may be connected in parallel. The total battery voltage may be increased by connecting parallel-connected battery cells in series.

FIG. 17B illustrates charging a battery to a full charge state.

Referring to FIG. 17B, a plurality of battery cells 1710, 1720, 1730, 1740, and 1750 are charged together. When the second battery cell 1720 and the fourth battery cell 1740 become fully charged, the third battery Cell 1730 may not yet reach a full state of charge.

At this time, when (or if) the over voltage protection setting is set too high compared to a full charge voltage, the first battery cell 1710 and the fifth battery cell 1750 may be overcharged (indicated by a box), and cause a fire.

FIG. 17C illustrates a full discharge state of battery.

Referring to FIG. 17C, when a plurality of battery cells 1710, 1720, 1730, 1740, and 1750 are discharged together, a cell 1730 may fall below a level capable of recharging and may decrease to a level requiring after-service (AS).

Complete discharge may mean (or refer to) a state in which 50% of Li+ of cathode active material has moved toward a negative electrode. In contrast, over-discharging is determined as (or may refer to) a situation in which the stable state of the cathode active material is collapsed or shall be collapsed (e.g., approaching collapse), and if the voltage is lower than a protection reference value, a permanent failure may be determined. Here, it may be preferable to replace the corresponding product with a new product.

Even if the product is managed at the level of (or with respect to) the protection reference value, AS may be possibly necessary due to low-current charging after problems occur, and/or long-term storage.

The capacity of the battery naturally decreases as time elapses. In a situation where cells having different production times are used in combination, when cells having a large difference in physical properties are mixed, the battery state may become imbalanced, and the efficiency and lifespan of the energy storage system may decrease. There is a possibility of a safety accident due to over-charging, and/or over-discharging.

According to an embodiment of the present disclosure, the batteries having a series structure (or configuration) are converted into a parallel (or configuration) by switching the series/parallel nature of the battery cell connection structure (or configuration), and the energy storage system 1 itself can correct the imbalance between the batteries.

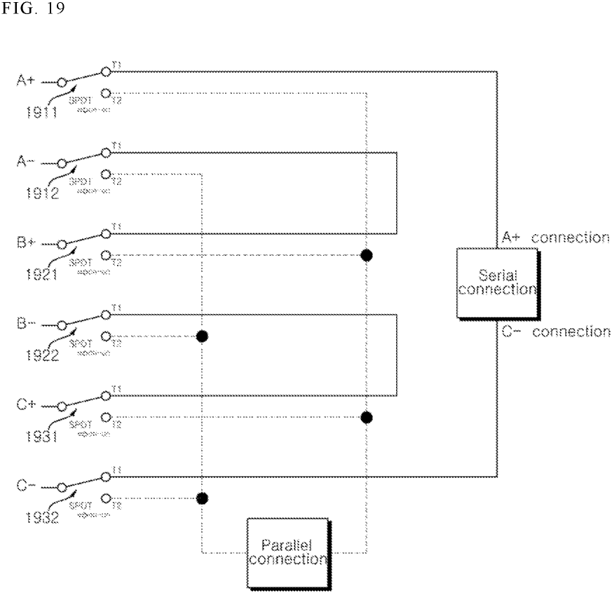

FIGS. 18 to 20 are diagrams for explaining a battery connection structure (or configuration) according to an embodiment of the present disclosure.

The energy storage system 1 according to an embodiment of the present disclosure includes a plurality of cell arrays 102, each including a respective plurality of battery cells 101 connected in parallel. The cell array 102 in which the plurality of battery cells 101 are connected in parallel may be the above-described first cell array 102.

A set of a plurality of cell arrays 102 connected in series may be the first and third cell groups 105 and 107 described above (e.g., with reference to FIG. 12).

In addition, the set of a plurality of cell arrays 102 connected in series may be a second cell array 103 including a plurality of battery cells 101 connected in series and in parallel and/or a second cell group 106 including the same.

The energy storage system 1 according to an embodiment of the present disclosure includes a plurality of switches 1931, 1932, 1933, 1934, 1935, 1936 which are connected (or coupled) to the plurality of cell arrays 102, and connect the plurality of cell arrays 102 in series. In addition, the plurality of switches 1931, 1932, 1933, 1934, 1935, 1936 may be switched (or operated) such that the plurality of cell arrays 102 are connected in parallel.

That is, the plurality of cell arrays 102 may be connected in series in a default state, and when the plurality of switches 1911, 1912, 1921, 1922, 1931, 1932 are switched, the connection state of the plurality of cell arrays 102 may be converted into a parallel structure (or configuration), in which the plurality of cell arrays 102 are connected in parallel. The plurality of switches 1911, 1912, 1921, 1922, 1931, and 1932 may be switched (or operated) to convert from a configuration where the switches connect a positive terminal of a cell array of the plurality of cell arrays 101 to the negative terminal of another cell array, to a configuration where the switches connect the positive terminals of the plurality of cell arrays 101 to each other and connect the negative terminals of the plurality of cell arrays 101 to each other.

FIGS. 18 to 20 illustrate three cell arrays 102 in which four battery cells 101 are connected in parallel, in order to intuitively display the connection configuration. In addition, three cell arrays 102 may be connected in series. In this case, a configuration in which four battery cells are connected in parallel and three cell arrays 102 are connected in series may be a default state (structure of 3S4P).

One of switches 1911, 1912, 1921, 1922, 1931, and 1932 may be connected to a positive terminal of the plurality of cell arrays 102, and another one of switches 1911, 1912, 1921, 1922, 1931, and 1932 may be connected to a negative terminal of the plurality of cell arrays 102 .

Referring to FIGS. 18 to 20, a cell array A 1810 includes four battery cells 1811, 1812, 1813, and 1814 connected in parallel. A first switch 1911 may be connected (or coupled) to a positive terminal A+ of the cell array A 1810, and a second switch 1912 may be connected (or coupled) to a negative terminal A- of the cell array A 1810. Since the four battery cells 1811, 1812, 1813, and 1814 connected in parallel have the same voltage, the voltage of the cell array A 1810, i.e., the voltage between the positive terminal A+ and the negative terminal A-, is the same as (or equal to) the respective voltages of the battery cells 1811, 1812, 1813, 1814.

A cell array B 1820 includes four battery cells 1821, 1822, 1823, 1824 connected in parallel. A third switch 1921 may be connected to the positive terminal B+ of the cell array B 1820, and a fourth switch 1922 may be connected to the negative terminal B- of the cell array B 1820. The voltage of the cell array B 1820, i.e., the voltage between the positive terminal B+ and the negative terminal B-, is the same as (or equal to) the respective voltages of the battery cells 1821, 1822, 1823, and 1824.

A cell array C 1830 includes four battery cells 1831, 1832, 1833, and 1834 connected in parallel. A fifth switch 1931 may be connected to the positive terminal C+ of the cell array C 1830, and a sixth switch 1932 may be connected to the negative terminal C- of the cell array C 1830. The voltage of the cell array C 1830, i.e., the voltage between the positive terminal C+ and the negative terminal C-, is the same as (or equal to) the respective voltages of the battery cells 1831, 1832, 1833, and 1834.

The four battery cells 101 connected in parallel in one cell array 102 have the same potential difference, but when the other cell arrays 102 continuously charge/discharge, a voltage difference may occur. For example, the battery cells of the cell array A 1810 have the same potential difference. However, the potential difference may not be equal to the potential difference of the battery cells of the cell array B 1820.

The energy storage system 1 according to an embodiment of the present disclosure may operate a plurality of switches 1911, 1912, 1921, 1922, 1931, 1932 to match the voltage balance of the cell arrays 1810, 1820, 1830, when a voltage difference of a switching reference value (e.g., 0.5 V) or higher set based on a natural capacity decrease rate and yield occurs (or appears) between the cell arrays 1810, 1820, 1830.

The voltage of the cell array 1810 is the same as the voltages of the battery cells included therein (battery cells 1811, 1812, 1813, 1814). Similarly, the voltage of the cell array 1820 is the same as the voltages of the battery cells included therein (battery cells 1821, 1822, 1823, 1824). Similarly, the voltage of the cell array 1830 is the same as the voltages of the battery cells included therein (battery cells 1831, 1832, 1833, 1834). Therefore, when the voltages of the cell arrays (1810, 1820, 1830) are matched, the voltages of the battery cells {(1811, 1812, 1813, 1814), (1821, 1822, 1823, 1824), (1831, 1832, 1833, 1834)} are also matched.

According to an embodiment of the present disclosure, the connection structure (or configuration) of the battery cells having a series/parallel structure (or configuration) is converted by switching in terms of a circuit. In addition, a cell balancing circuit may be configured using a number of switches (e.g., six switches in the examples of FIGS. 18 to 20) smaller than the number of cells (e.g., twelve cells in the examples of FIGS. 18 to 20), by connecting the switches (1911, 1912, 1921, 1922, 1931, 1932) to the cell arrays (1810, 1820, 1830) containing the battery cells {(1811, 1812, 1813, 1814), (1821, 1822, 1823, 1824), (1831, 1832, 1833, 1834)} connected in parallel. As the number of cells increases, the effect of reducing the number of switches may be greater.

The plurality of switches 1911, 1912, 1921, 1922, 1931, and 1932 may be (or include) a single pole double throw (SPDT) switch. For example, each of the switches 1911, 1912, 1921, 1922, 1931, and 1932 may be an SPDT switch. As a device that can be used for SPDT, a switch circuit using transistor (TR)/FET low power consumption is available.

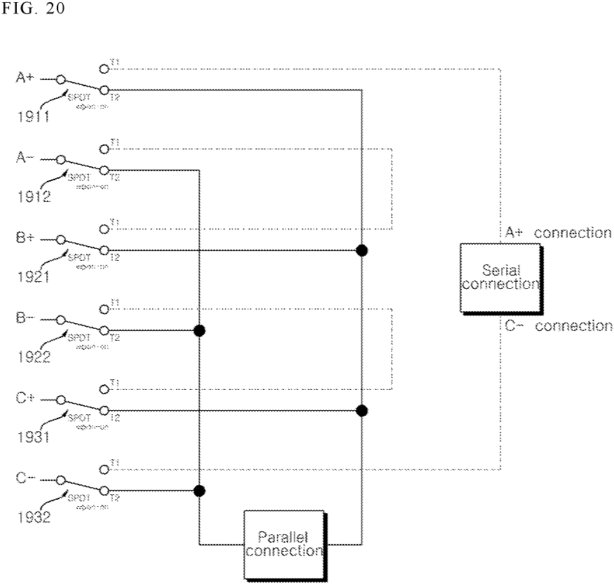

FIGS. 19 and 20 are diagrams illustrating a switching of connection structure (or configuration) using an SPDT switch. FIG. 19 illustrates a series structure (or configuration), and FIG. 20 illustrates a parallel structure (or configuration).

Referring to FIG. 19 (see, e.g., solid-line connections), the plurality of switches 1911, 1912, 1921, 1922, 1931, and 1932 form a path connected to a first output terminal T1 (e.g., the positive terminal A+ of the cell array A 1810). Accordingly, the negative terminal A- of the cell array A 1810 may be connected to the positive terminal B+ of the cell array B 1820, and the negative terminal B- of the cell array B 1820 may be connected to the positive terminal C+ of the cell array C 1830. In this way, the cell arrays 1810, 1820, and 1830 may be connected in series.

Referring to FIG. 20 (see, e.g., solid-line connections), the plurality of switches 1911, 1912, 1921, 1922, 1931, and 1932 form a path connected to a second output terminal T2, respectively. Accordingly, the negative terminal A- of the cell array A 1810, the negative terminal B- of the cell array B 1820, and the negative terminal C- of the cell array C 1830 are connected, and the positive terminal A+ of the cell array A 1810, the positive terminal B+ of the cell array B 1820, and the positive terminal C+ of the cell array C 1830 are connected. In this way, the cell arrays 1810, 1820, and 1830 may be connected in parallel. When the cell arrays 1810, 1820, and 1830 are connected in a parallel structure (or configuration), twelve battery cells [(1811, 1812, 1813, 1814), (1821, 1822, 1823, 1824), (1831, 1832, 1833, 1834)] may be connected in a single parallel structure (or configuration), and be balanced with the same voltage.

The number of the plurality of switches 1911, 1912, 1921, 1922, 1931, and 1932 may be twice the number of the plurality of cell arrays 101 connected in series. Referring to FIGS. 18 to 20, in a 3S4P structure (a cell structure in which three cell arrays may be connected in series and four cells are connected in parallel in each cell array), a structure where all of twelve battery cells (1811, 1812, 1813, 1814) (1821, 1822, 1823, 1824) (1831, 1832, 1833, 1834) are in parallel can be made by using six SPDTs (1911, 1912, 1921, 1922, 1931, 1932). In the case of 28S9P, if 56 SPDTs are used, all of 252 batteries can be made to be a parallel structure so as to be balanced.

According to an embodiment of the present disclosure, an imbalance between the battery packs 10 containing a plurality of battery cells 101 connected in series and parallel can also be adjusted. When switches are disposed in (or at) the terminals of the battery pack 10, and a voltage imbalance occurs between the battery packs 10, it is converted to a parallel structure (or configuration) in which (+) terminal is connected to (+) terminal and in which (-) terminal is connected to (-) terminal, so that the balance can be achieved by itself.

If each battery pack 10 is a 7S14P structure having a default state in which 14 battery cells 101 are connected in parallel (in each cell array 102) and 7 cell arrays 102 are connected in series, all of 98 battery cells 101 may be connected in parallel by using 14 SPDT switches.

If the energy storage system 1 includes four 7S14P battery packs 10, the energy storage system 1 may balance 392 battery cells 101 by using 56 SPDT switches.

According to an embodiment of the present disclosure, a balancing circuit capable of converting a series/parallel structure (or configuration) with a simple structure may be configured.

The battery management system 34 may monitor state information of the battery 35 and control a connection structure of the battery 35. The battery management system 34 may control the plurality of switches 1911, 1912, 1921, 1922, 1931, and 1932 based on voltage difference(s) between the plurality of cell arrays 102.

When it is determined that an imbalance state has occurred while monitoring the current battery voltage state and current state, the battery management system 34 operates the switches 1911, 1912, 1921, 1922, 1931, 1932 such that the connection structure (or configuration) of the plurality of cell arrays 101 or the plurality of battery packs 10 is converted into a parallel structure (or configuration).

When a voltage difference of (or between) the plurality of cell arrays 102 is greater than or equal to a first reference value, in a state where the full charge condition is satisfied, during charging, the battery management system 34 may change the connection state of the plurality of cell arrays 102 from a series structure (or configuration) to a parallel structure (or configuration).

Then, in the parallel structure (or configuration) state, when the voltage difference of the plurality of cell arrays 101 is less than a second reference value, the battery management system 34 may change the connection state of the plurality of cell arrays 101 from a parallel structure (or configuration) to a series structure (or configuration). Here, the second reference value may be set lower than the first reference value.

Alternatively, when the voltage difference between the plurality of cell arrays 101 is greater than or equal to a certain reference value, the battery management system 34 may change the connection state of the plurality of cell arrays from a series structure (or configuration) to a parallel structure (or configuration), and when a preset time elapses, may change the connection state of the plurality of cell arrays 101 from a parallel structure (or configuration) to a series structure (or configuration).

According to an embodiment of the present disclosure, the battery imbalance can be adjusted, thereby increasing the degree of freedom in designing a series/parallel structure (or configuration) of a desired capacity.

When the serial-to-parallel conversion structure (or configuration) according to the embodiment of the present disclosure is reflected in the production process of the energy storage system 1, it is easy to assemble with the same capacity even with the battery cells 101 having different production times, and the voltage difference between the batteries 35 can be reduced. Accordingly, first-in-first-out and inventory expansion are possible, productivity can be improved, and manufacturing cost can be reduced.

According to an embodiment of the present disclosure, for safety, the battery management system 34 may turn off some internal power sources of the energy storage system 1, and may switch the plurality of switches 1911, 1912, 1921, 1922, 1931, 1932. The battery management system 34 may operate the switches 1911, 1912, 1921, 1922, 1931, 1932, after turning off the internal power of the battery.

The battery management system 34 includes battery pack circuit boards 220 which are disposed in each of the plurality of battery packs 10, and obtain state information of a plurality of battery cells 101 contained in each battery pack 10, and a main circuit board 34a which is connected to the battery pack circuit boards 220 by a communication line, and receives state information obtained from each battery pack 10 by the battery pack circuit boards 220.

According to an embodiment of the present disclosure, it is possible to protect a control circuit 34a that performs the main function of the battery management system 34 and manages the plurality of battery packs 10, by designing the control circuit 34a including a configuration (particularly, a configuration for safety control) for managing the battery 35 separately from a battery cell sensing circuit 220.

According to an embodiment of the present disclosure, it is possible to prevent overcharging due to voltage imbalance, thereby eliminating the possibility of ignition. In addition, according to an embodiment of the present disclosure, it is possible to prevent (e.g., at an earlier time) the complete discharging of the battery.

According to an embodiment of the present disclosure, the plurality of battery cells 101 connected in parallel may be respectively connected to the above-described bus bar 150.

In addition, one input terminal (of each) of the plurality of switches 1911, 1912, 1921, 1922, 1931, 1932 is connected to the positive terminal of the plurality of cell arrays 102. Another input terminal of (each of) the plurality of switches 1911, 1912, 1921, 1922, 1931, 1932 may be connected to the negative terminal of the plurality of cell arrays 102. In addition, two output terminals of the plurality of switches 1911, 1912, 1921, 1922, 1931, and 1932 may be connected to different bus bars 150. Accordingly, the connection structure (or configuration) of the plurality of cell arrays 101 can be converted by changing the bus bar 150 connected by the switching operation of the switch 1911, 1912, 1921, 1922, 1931, 1932.

When the connection structure (or configuration) of the plurality of cell arrays 102 is a series structure in the default state, the negative terminal of any one cell array 102 may be connected to, and the positive terminal of another cell array 102 may be connected to any one bus bar 150. In this way, a plurality of cell arrays 102 may be connected in series. When the switch 1911, 1912, 1921, 1922, 1931, 1932 operates, the output of the cell arrays 102 may be connected to another bus bar 150 to form a parallel structure (or configuration).

As described with reference to FIGS. 1 to 20, the energy storage system 1 according to an embodiment of the present disclosure may include a plurality of battery packs 10 including a first battery module 100a, a second battery module 100b disposed to face the first battery module 100a, and a high current bus bar 196 connecting the first battery module 100a and the second battery module 100b.

Each of the first battery module 100a and the second battery module 100b includes a plurality of cell arrays 102, each including a respective plurality of battery cells 101 connected in parallel, and a plurality of switches 1911, 1912, 1921, 1922, 1931, 1932 which are connected (or coupled) to the plurality of cell arrays 102, and connect the plurality of cell arrays 102 in series. The plurality of switches 1911, 1912, 1921, 1922, 1931, and 1932 may be switched (or operated) to perform a balancing operation so that the plurality of cell arrays 102 may be connected in parallel.

The plurality of switches 1911, 1912, 1921, 1922, 1931, and 1932 may be (or include) a single pole double throw (SPDT) switch.

The battery management system 34 may control the plurality of switches 1911, 1912, 1921, 1922, 1931, and 1932 based on the voltage difference(s) between the plurality of cell arrays 102.

For example, when the voltage difference of the plurality of cell arrays 102 is equal to or greater than a first reference value in a state during charging where the full charge condition is satisfied, the battery management system 34 may change the connection state of the plurality of cell arrays from a series structure (or configuration) to a parallel structure (or configuration).

When the voltage difference of the plurality of cell arrays 102 is less than a second reference value in the parallel structure (or configuration) state, the battery management system 34 may change the connection state of the plurality of cell arrays 102 from a parallel structure (or configuration) to a series structure (or configuration).

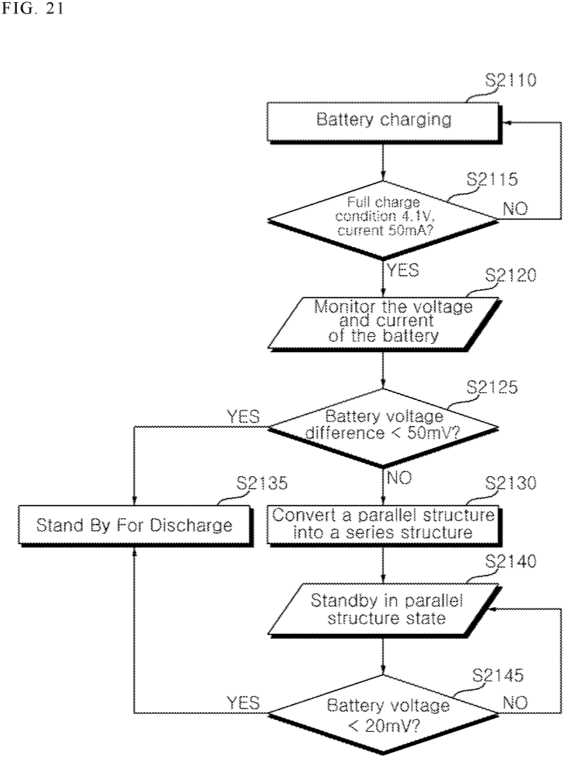

FIG. 21 is a flowchart illustrating a method of operating an energy storage system according to an embodiment of the present disclosure.

Referring to FIG. 21, the battery 35 may be charged (S2110), until the battery 35 satisfies a full charge condition (e.g., 4.1 V, 50 mA) (S2115).

When the battery is charged, if the battery cell 101 having the highest voltage in battery 35 reaches the full charge condition, the remaining battery cells 101 cannot be charged even though they need to be charged (e.g., even though they are capable of being charged further). In addition, when the battery is discharged, if the battery cell 101 having the lowest voltage reaches a full discharge condition, even a more usable battery cannot be discharged further. Therefore, there is a need for a method to solve the voltage imbalance of the battery cell 101 during battery charging/discharging.

The battery management system 34 may monitor the voltage and current of the battery 35 (S2120). In the state where the full charge condition is satisfied (S2115), if the voltage difference of the plurality of cell arrays 102 is greater than or equal to the first reference value (e.g., 50mV) (S2125), the battery management system 34 may perform the balancing operation (see, e.g., S2130).

For example, as described with reference to FIGS. 18 to 20, the battery management system 34 may operate the plurality of switches 1911, 1912, 1921, 1922, 1931, and 1932 to change the connection state of the plurality of cell arrays from a series structure (or configuration) to a parallel structure (or configuration) (S2135).

In the parallel structure state (S2140), if the voltage difference of the plurality of cell arrays 102 is less than a second reference value (e.g., 20 mV) lower than the first reference value of S2125 (S2145), the battery management system 34 may determine that the imbalance state has been resolved. Therefore, in the parallel structure state (S2140), if the voltage difference of the plurality of cell arrays 102 is less than the second reference value (S2145), the battery management system 34 may prepare for discharging by changing the connection state of the plurality of cell arrays 102 from a parallel structure (or configuration) to a series structure (or configuration) (S2135).

The parallel structure change parameter (the first reference value (see S2125)) may arbitrarily set the battery lifespan and voltage difference, and the conditions for releasing to the series structure again (see S2145) can also be changed according to the temperature and the battery charging SOC.

According to an embodiment, the battery management system 34 maintains the parallel structure state for a certain time (S2140), and discharge can be prepared by automatically changing the connection state of the plurality of cell arrays 102 from a parallel structure (or configuration) to a series structure (or configuration) after the certain time has elapsed.

If there is an imbalance between the batteries, the usable capacity that can be used by consumers becomes smaller. Accordingly, when a set voltage difference occurs (S2125), the battery management system 34 may turn off the external power of the battery system, and facilitate a balance between the batteries in a parallel structure (or configuration) for a certain period of time. By applying a software (SW) timer, it operates normally after a certain period of time. The certain period of time of the timer is a parameter that can be applied differently depending on the temperature and the charge state of the SOC.

If the voltage difference of the plurality of cell arrays 102 is less than the first reference value (S2125), the battery management system 34 may control the battery 35 in a discharge standby state (S2135). In this case, since the plurality of cell arrays 102 are not changed from the serial structure (or configuration) that is a default state, it is not necessary to change the battery connection structure (or configuration).

According to at least one embodiment of the present disclosure, the lifespan, stability, and efficiency of the battery may be improved by reducing the voltage difference between the batteries.

In addition, according to at least one embodiment of the present disclosure, it is possible to prevent (e.g., at an earlier time) the complete discharge of the battery and improve the battery lifespan.

In addition, according to at least one embodiment of the present disclosure, it is possible to prevent overcharging due to battery imbalance, thereby reducing the possibility of ignition.

In addition, according to at least one embodiment of the present disclosure, battery imbalance may be adjusted with a small number of switches.

In addition, according to an embodiment of the present disclosure, a series/parallel structure (or configuration) of a desired capacity can be easily implemented, thereby increasing the design freedom of the battery cell module.

While the present invention has been particularly shown and described with reference to exemplary embodiments thereof, it will be understood by those of ordinary skill in the art that various changes in form and detail may be made herein without departing from the spirit and scope of the present invention as defined by the following claims and such modifications and variations should not be understood as being outside the scope of the technical idea or aspect of the present invention.

What is claimed is:

1. An energy storage system comprising:
a plurality of cell arrays, each comprising a respective plurality of battery cells connected in parallel; and
a plurality of switches coupled to the plurality of cell arrays, and configured to connect the plurality of cell arrays in series,
wherein the plurality of switches are operable to connect the plurality of cell arrays in parallel.

2. The energy storage system of claim 1, wherein the plurality of switches comprise a single pole double throw (SPDT) switch.

3. The energy storage system of claim 1, wherein a first switch of the plurality of switches is coupled to a positive terminal of the plurality of cell arrays, and a second switch of the plurality of switches is coupled to a negative terminal of the plurality of cell arrays.

4. The energy storage system of claim 1, wherein the plurality of switches are configured to be operated such that a positive terminal of one of the plurality of cell arrays is connected to a negative terminal of another one of the plurality of cell arrays, and then, positive terminals of the plurality of cell arrays are connected to each other and negative terminals of the plurality of cell arrays are connected to each other.

5. The energy storage system of claim 1, wherein a number of the plurality of switches is equal to two times a number of the plurality of cell arrays connected in series.

6. The energy storage system of claim 1, further comprising a battery management system configured to control the plurality of switches based on a voltage difference of the plurality of cell arrays.

7. The energy storage system of claim 6, wherein during charging, in a state in which a full charge condition is satisfied, the battery management system is further configured to change a connection state of the plurality of cell arrays from a series configuration to a parallel configuration based on the voltage difference of the plurality of cell arrays being equal to or greater than a first reference value.

8. The energy storage system of claim 6, wherein in a parallel configuration state, the battery management system is further configured to change a connection state of the plurality of cell arrays from a parallel configuration to a series configuration based on the voltage difference of the plurality of cell arrays being less than a second reference value.

9. The energy storage system of claim 6, wherein the battery management system is further configured to:
change a connection state of the plurality of cell arrays from a series configuration to a parallel configuration based on the voltage difference of the plurality of cell arrays being equal to or greater than a certain reference value; and
change the connection state of the plurality of cell arrays from the parallel configuration to the series configuration based on a preset time elapsing.

10. The energy storage system of claim 6, wherein the battery management system is further configured to turn off some internal power sources of the energy storage system and operate the plurality of switches.

11. The energy storage system of claim 6, further comprising a plurality of battery packs, each comprising a respective plurality of cell arrays.

12. The energy storage system of claim 11, wherein the battery management system comprises:
battery pack circuit boards disposed in each of the plurality of battery packs, and configured to obtain state information of the plurality of battery cells of each battery pack; and
a main circuit board coupled to the battery pack circuit boards by a communication line, and configured to receive state information obtained from each battery pack by the battery pack circuit boards.

13. The energy storage system of claim 12, wherein the plurality of battery packs are connected in series by a power line,
wherein the power line is connected to the main circuit board.

14. The energy storage system of claim 1, further comprising a plurality of bus bars to which the plurality of battery cells connected in parallel are connected.

15. The energy storage system of claim 14,
wherein one input terminal of the plurality of switches is coupled to a positive terminal or a negative terminal of the plurality of cell arrays, and
wherein two output terminals of the plurality of switches are coupled to different bus bars.

16. An energy storage system comprising a plurality of battery packs comprising a first battery module, a second battery module disposed to face the first battery module, and a high current bus bar connecting the first battery module and the second battery module,
wherein each of the first battery module and the second battery module comprises:
a plurality of cell arrays, each comprising a respective plurality of battery cells connected in parallel; and
a plurality of switches coupled to the plurality of cell arrays and configured to connect the plurality of cell arrays in series,
wherein the plurality of switches are operable to connect the plurality of cell arrays in parallel.

17. The energy storage system of claim 16, wherein the plurality of switches comprise a single pole double throw (SPDT) switch.

18. The energy storage system of claim 16, further comprising a battery management system configured to control the plurality of switches based on a voltage difference of the plurality of cell arrays.

19. The energy storage system of claim 18, wherein during charging, in a state in which a full charge condition is satisfied, the battery management system is further configured to change a connection state of the plurality of cell arrays from a series configuration to a parallel configuration based on the voltage difference of the plurality of cell arrays being equal to or greater than a first reference value.

20. The energy storage system of claim 18, wherein in a parallel configuration state, the battery management system is further configured to change a connection state of the plurality of cell arrays from a parallel configuration to a series configuration based on the voltage difference of the plurality of cell arrays being less than a second reference value.
